(19) United States
(12) Patent Application Publication
(10) Pub. No.: US 2018/0075951 A1
(43) Pub. Date: Mar. 15, 2018

(54) WIRE HARNESS MANUFACTURING METHOD AND CONNECTOR HOLDING PART SUPPORTING DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Tomohide MAKI, Mie (JP); Shigeto KATO, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 15/560,366

(22) PCT Filed: Mar. 14, 2016
(86) PCT No.: PCT/JP2016/057917

§ 371 Date: Sep. 21, 2017

(30) Foreign Application Priority Data
Mar. 31, 2015 (JP) 2015-072643

(51) Int. Cl. H01B 13/012; B23P 21/00; H05K 13/06; H01R 43/20

(52) U.S. Cl. CPC H01B 13/01209; H01R 43/20; H05K 13/06; B23P 21/00

(57) ABSTRACT

The present invention provides technology that makes it possible to perform branch formation on a semi-finished product in which electrical wires are inserted into connectors, without placing the semi-finished product on a jig board, and improving manufacturing flexibility. A wire harness manufacturing method includes step (a) and step (b). The step (a) is preparing a member in which a plurality of connectors into which electrical wires are inserted are respectively held by connector holding parts such that the electrical wires dangle, and supporting parts that are able to support the connector holding parts in a first direction that is orthogonal to a vertical direction are arranged in a second direction that is orthogonal to the first direction. The step (b) is forming branches from portions of the electrical wires that dangle from the connectors, with the connectors remaining in a state of being held by the connector holding parts.

### TECHNICAL FIELD

The present invention relates to a method for manufacturing a wire harness that is to be mounted on a vehicle or the like.

### BACKGROUND ART

Patent Document 1 discloses a method for manufacturing a wire harness by which a plurality of electrical wires are arranged on a jig board according to wiring routes in a vehicle, and the electrical wires are divided into branches and tied together according to the wiring routes.

However, in order to form branches on a jig board as disclosed in Patent Document 1, it is necessary to place a semi-finished product, in which circuitry has been completed by inserting electrical wires into connectors, onto the jig board, which is troublesome. Also, there is the risk of a problem such as electrical wires becoming tangled when the semi-finished product is placed on the jig board.

Considering this problem, Patent Document 2 discloses a method for shaping a wire harness without placing it on the jig board, using a harness shaping device for routing a plurality of electrical wires along a plurality of vertical rails.

### CITATION LIST

### Patent Documents

Patent Document 1: JP2014-32840A

Patent Document 2: JP2008-192456A

### SUMMARY OF INVENTION

### Technical Problem

However, according to Patent Document 2, one connector is arranged on each of the plurality of vertical rails, and hence the wire harness is shaped in the state where the connectors are arranged in a horizontal row. Therefore, there is a risk that what wire harness can be manufactured depends on the length of electrical wires that connect the connectors at both ends. Also, there is the risk of being unable to form branches that have a complex shape.

Therefore, the present invention aims to provide technology that makes it possible to perform branch formation on a semi-finished product in which electrical wires are inserted into connectors, without placing the semi-finished product on a jig board, while supporting a wider variety of branch shapes.

### Solution to Problem

To solve the above-described problems, a wire harness manufacturing method according to a first aspect includes (a) a step of preparing a member in which a plurality of connectors into which electrical wires are inserted are respectively held by connector holding parts such that the electrical wires dangle, and supporting parts that are able to support the connector holding parts in a first direction that is orthogonal to a vertical direction are arranged in a second direction that is orthogonal to the first direction; and (b) a step of forming branches from portions of the electrical wires that dangle from the connectors, with the connectors remaining in a state of being held by the connector holding parts.

A wire harness manufacturing method according to a second aspect is the wire harness manufacturing method according to the first aspect, wherein, in the step (b), the connector holding parts are arranged so as to be movable relative to each other.

A wire harness manufacturing method according to a third aspect is the wire harness manufacturing method according to the first or second wire harness manufacturing method, wherein, in the step (a), the connector holding parts are directly or indirectly attached to rod-shaped connector bars so as to be slidable in a lengthwise direction of the connector bars, and the plurality of connector bars are provided in a direction that is orthogonal to the lengthwise direction thereof.

A wire harness manufacturing method according to a fourth aspect is the wire harness manufacturing method according to the third aspect, wherein the connector holding parts are attached to connector holding part attachment parts so as to be slidable in a direction that is orthogonal to the lengthwise direction of the connector bars, the connector holding part attachment parts being attached to the connector bars so as to be slidable in the lengthwise direction of the connector bars.

A wire harness manufacturing method according to a fifth aspect is the wire harness manufacturing method according to the third or fourth aspect, wherein the plurality of connector bars are arranged so as to be movable relative to each other in a direction in which the connector bars are arranged.

A wire harness manufacturing method according to a sixth aspect is the wire harness manufacturing method according to any one of the third to fifth aspects, wherein the connectors are held on the connector bars when the electrical wires are inserted into the connectors, and the connector bars used when the electrical wires were inserted are used as they are when branches are formed.

A wire harness manufacturing method according to a seventh aspect is the wire harness manufacturing method according to any one of the first to sixth aspects, wherein, in the step (b), image data of the electrical wires dangling from the connectors is acquired, the image data is processed to measure a distance from the connectors, and positions at which branches are to be formed are determined.

A connector holding part supporting device according to an eighth aspect includes a plurality of supporting parts that are able to directly or indirectly support a plurality of connector holding parts such that electrical wires that extend from the connectors dangle, the connector holding parts being able to hold connectors, wherein the supporting parts are able to support a plurality of connector holding parts in a first direction that is orthogonal to a vertical direction, and the plurality of supporting parts are arranged in a second direction that is orthogonal to the first direction.

### Advantageous Effects of Invention

With the wire harness manufacturing method according to the first to seventh aspects, the plurality of connectors into which the electrical wires are inserted are held by the connector holding parts such that the electrical wires dangle, and branches from portions of the electrical wires dangling from the connectors are formed, with the connectors remaining in the state of being held by the connector holding parts. Therefore, it is possible to perform branch formation on a semi-finished product in which the electrical wires have been inserted into the connectors, without placing the semi-finished product on a jig board. In this regard, since the supporting parts that can support the plurality of connector holding parts in the first direction that is orthogonal to the vertical direction are arranged in the second direction that is orthogonal to the first direction, the method is applicable to a wide variety of branch shapes.

In particular, with the wire harness manufacturing method according to the second aspect, in the step (b), the plurality of connector holding parts are arranged so as to be movable relative to each other, and therefore, it is easier to adjust the relative positional relationship between the connectors. In particular, for example, when forming branches, it is possible to arrange the connectors in an arrangement that is more similar to the arrangement in a vehicle. Consequently, it is possible to obtain a wire harness that has a shape that is more similar to the shape of the wire harness when mounted on a vehicle.

In particular, with the wire harness manufacturing method according to the third aspect, in the step (a), the connector holding parts are directly or indirectly attached to the rod-shaped connector bars so as to be slidable in the lengthwise direction of the connector bars, and therefore, it is easier to adjust the relative positional relationship between the connectors. Also, since a plurality of connector bars are arranged in a direction that is orthogonal to the lengthwise direction thereof, it is possible to two-dimensionally arrange the connector holding parts when viewed from the direction in which the electrical wires are inserted. Consequently, it is possible to obtain a wire harness that has a shape that is more similar to the shape of the wire harness when mounted on a vehicle.

In particular, with the wire harness manufacturing method according to the fourth aspect, the connector holding parts are attached to the connector holding part attachment parts that are attached to the connector bars so as to be slidable in the lengthwise direction of the connector bars, so as to be slidable in a direction that is orthogonal to the lengthwise direction of the connector bars. Therefore, it is easier to adjust the relative positional relationship between the connectors. Also, when the operator forms branches, for example, the operator can more easily specify the positions at which branches are to be formed, by matching the positions of the connectors relative to the connector bars with the distance from the connectors to the positions at which branches are to be formed.

In particular, with the wire harness manufacturing method according to the fifth aspect, the plurality of connector bars are arranged so as to be movable relative to each other in the direction in which they are arranged. Therefore, it is easier to adjust the relative positional relationship between the connectors. Consequently, it is possible to obtain a wire harness that has a shape that is more similar to the shape of the wire harness when mounted on a vehicle.

In particular, with the wire harness manufacturing method according to the sixth aspect, when the electrical wires are inserted into the connectors, the connectors are held on the connector bars, and the connector bars that were used when the electrical wires were inserted are used as they are when branches are formed. That is, the same connector bars are used from when the electrical wires are inserted to when branches are formed. Consequently, it is possible to suppress the number of manufacturing steps from increasing due to the connectors being re-mounted at the time of transition from the task of inserting electrical wires to the task of forming branches.

In particular, with the wire harness manufacturing method according to the seventh aspect, in the step (b), the distance from the connectors is measured by obtaining the image data of the electrical wires that dangle from the connectors and processing the image data, and thus the positions at which branches are to be formed are determined. Therefore, it is possible to realize automation of the task related to the formation of branches.

The connector holding part supporting device according to the eighth aspect includes a plurality of supporting parts that are able to directly or indirectly support a plurality of connector holding parts such that electrical wires that extend from connectors dangle, the connector holding parts being able to hold the connectors. Therefore, by forming branches in dangling portions of the electrical wires, it is possible to perform branch formation on a semi-finished product in which electrical wires are inserted into connectors, without placing the semi-finished product on a jig board. Also, the supporting parts are able to support a plurality of connector holding parts so as to be arranged in a first direction that is orthogonal to the vertical direction, and the plurality of supporting parts are arranged in a second direction that is orthogonal to the first direction. Therefore, it is possible to improve manufacturing flexibility.

### BRIEF DESCRIPTION OF DRAWINGS

FIG. 1 is a workflow diagram showing a wire harness manufacturing method according to an embodiment.

FIG. 2 is a laid-out plan view of an example of a wire harness that is manufactured using the wire harness manufacturing method according to the embodiment.

FIG. 3 is a perspective view showing a connector holding part supporting device.

FIG. 4 is a schematic side view showing the connector holding part supporting device.

FIG. 5 is a diagram in which a part of FIG. 3 is enlarged. FIG. 6 is a schematic perspective view showing an electrical wire inserting device.

FIG. 7 illustrates an operation that is performed to insert electrical wires.

FIG. 8 illustrates an operation that is performed to insert electrical wires.

FIG. 9 illustrates an operation that is performed to insert electrical wires.

FIG. 10 illustrates an operation that is performed to insert electrical wires.

FIG. 11 is a schematic view showing an electrical wire group processing device.

FIG. 12 illustrates an operation that is performed to form branches from electrical wires.

FIG. 13 illustrates an operation that is performed to form branches from electrical wires.

FIG. 14 illustrates an operation that is performed to form branches from electrical wires.

FIG. 15 illustrates an operation that is performed to form branches from electrical wires.

FIG. 16 illustrates an operation that is performed to form branches from electrical wires.

FIG. 17 illustrates a wire harness manufacturing method according to a modification.

FIG. 18 illustrates a wire harness manufacturing method according to another modification.

FIG. 19 illustrates a wire harness manufacturing method according to yet another modification.

FIG. 20 illustrates that intermediate portions of electrical wires are supported.

### DESCRIPTION OF EMBODIMENTS

### Embodiment

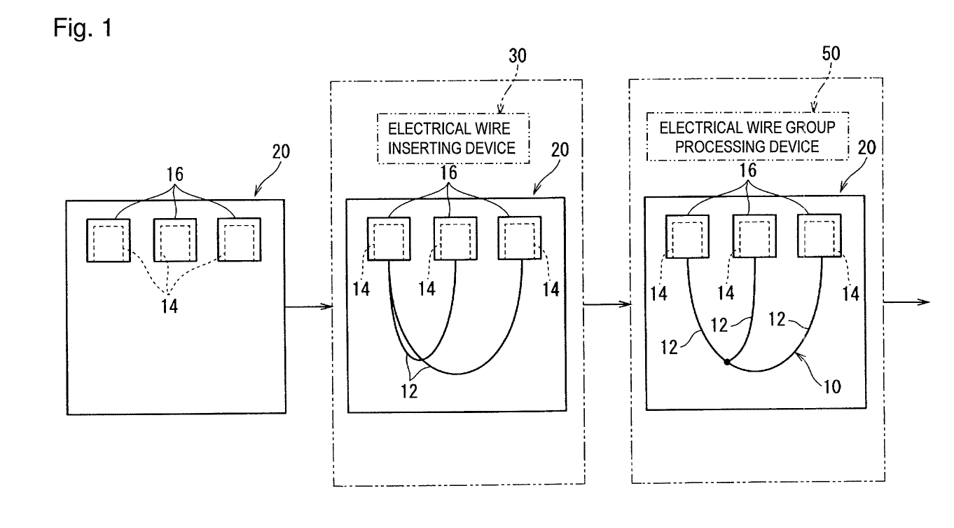

The following describes a wire harness manufacturing method according to an embodiment. Here, the overall flow of the wire harness manufacturing method according to the embodiment will be described first with reference to FIG. 1, and then each task will be described. FIG. 1 is a workflow diagram showing the wire harness manufacturing method according to the embodiment.

The first step of the wire harness manufacturing method according the embodiment is to prepare a plurality of connectors 14, a plurality of connector holding parts 16, and a connector holding part supporting device 20. Each connector holding part 16 is configured to hold at least one connector 14. The connector holding part supporting device 20 is configured to hold a plurality of connector holding parts 16. The connector holding parts 16 are set to the connector holding part supporting device 20, and the connectors 14 are set to the connector holding parts 16.

Next, the connector holding part supporting device 20 to which the connectors 14 have been set is transported to an electrical wire inserting device 30, and electrical wires 12 are inserted into the connectors 14 that have been set to the connector holding part supporting device 20.

Next, the connector holding part supporting device 20, in which predetermined electrical wires 12 have been inserted into each connector 14, is transported to an electrical wire group processing device 50, branches from the electrical wires 12 are formed, and thus a wire harness 10 is formed. Here, when the electrical wires 12 are inserted into the connectors 14, the electrical wires 12 extend independent of each other. The electrical wire group processing device 50 performs the task of maintaining the plurality of electrical wires 12, which extend independent of each other, in the form in which the electrical wires 12 are branched along installation routes. Note that, in each drawing, electrical wires 12 that pass through the same route are represented as a single line. Therefore, in each drawing, it is possible that a single line actually represents a bundle of electrical wires 12.

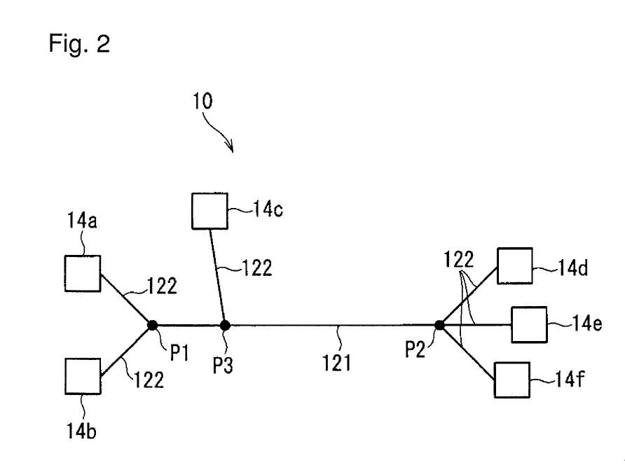

Here, the wire harness 10 that is manufactured using the wire harness manufacturing method according to the embodiment will be described with reference to FIG. 2 as well. FIG. 2 is a laid-out plan view of an example of a wire harness 10 that is manufactured using the wire harness manufacturing method according to the embodiment.

The wire harness 10 that is to be processed has a configuration in which the plurality of electrical wires 12 are divided into branches and tied together. From the branches of the wire harness 10, the electrical wires 12 are inserted into and connected to the connectors 14. This wire harness 10 is built into a vehicle, and the connectors 14 are connected to various kinds of electronic components that are mounted on the vehicle. Thus, the wire harness 10 serves to electrically connect various kinds of electronic components that are mounted on the vehicle. The electrical wires 12 included in the wire harness 10 are divided into branches and tied together according to installation routes in the vehicle.

Each electrical wire 12 includes a core, which is a wire rod that is mainly made of a metal such as copper or aluminum, and an insulative coating that envelops the core. The insulative coating is, for example, a member that is mainly made of a synthetic resin such as polyethylene, vinyl chloride, or polyamide nylon.

As described above, the connectors 14 are connected to end portions of the electrical wires 12. The electrical wires 12 are connected to the connectors 14 via, for example, terminals that are press-fitted or welded to, and thus connected to, the end portions of the electrical wires 12. Note that the terminals are, for example, metal members that are mainly made of metal such as copper or tin.

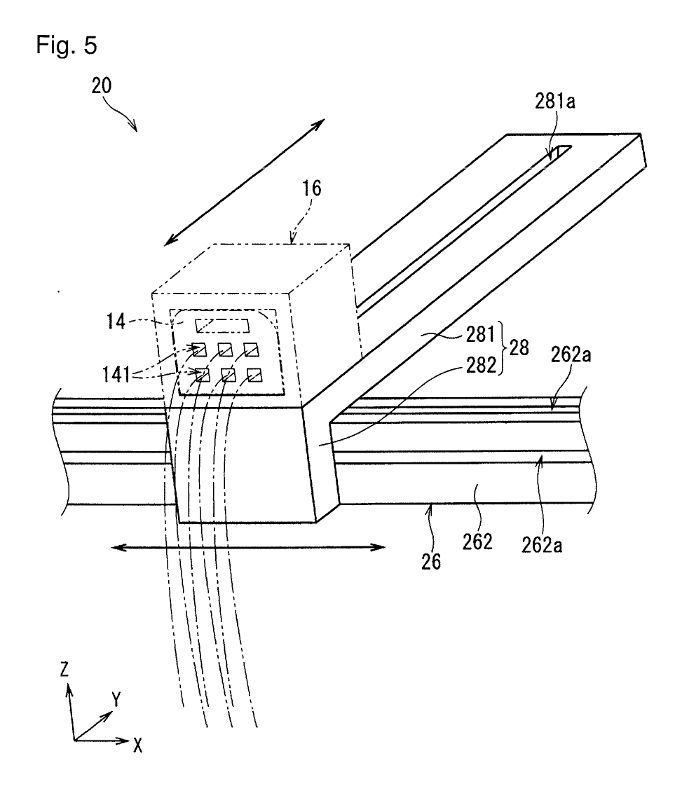

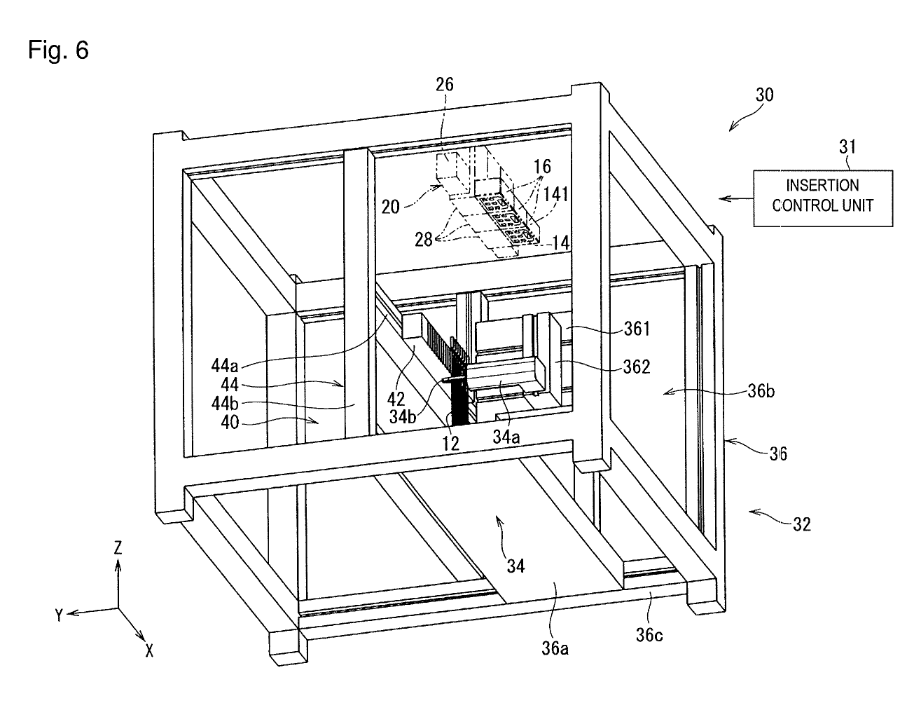

The body of each connector 14 is, for example, formed as an integrated piece using an insulative resin material such as a polybutylene terephthalate (PBT) or ABS resin. A plurality of cavities 141 are formed in the main surface, which is the surface to which electrical wires 12 are to be connected, of the body of each connector 14 (see FIG. 5).

The cavities 141 are open structures that house end portions (e.g. terminals) of electrical wires 12. Each cavity 141 has a certain depth in a direction that is, for example, substantially orthogonal to the main surface of the body of the connector 14. The electrical wires 12 housed in the cavities 141 are positioned and held at a predetermined depth in the cavities 141. Although the number of cavities 141 preferably corresponds to the number of electrical wires 12, the number is not particularly limited to such a number. In the present embodiment, a total number of six cavities 141 are provided in rows and columns. However, it is only necessary that a plurality of cavities 141 are provided. In addition, it is not necessary that the cavities 141 have the same depth and the same width, and a cavity 141 that has a different depth and width may be included.

A connector 14 in which electrical wires 12 are held in the cavities 141 thereof is connected to a partner connector at a surface that is opposite the main surface thereof, for example.

In the following description, the case of manufacturing the wire harness 10 that branches off as shown in FIG. 2 will be described as an example. Of course, a wire harness 10 that has a different branch shape may be manufactured. In the wire harness 10, two branch lines 122 extend from an end portion of a trunk line 121 on one side, three branch lines 122 extend from an end portion of the trunk line 121 on the other side, and one branch line 122 extends from an intermediate portion of the trunk line 121. In this regard, connectors 14 are connected to end portions of the branch lines 122. In the following description, the connectors 14 are referred to as connectors 14a to 14f when they need to be specifically distinguished form each other.

In some cases, branching points are referred to as a primary branching point or a secondary branching point, in order from the connector 14 side. That is, a primary branching point is a branching point that is formed by assembling portions of electrical wires 12 that extend from connectors 14, relative to which no branching points are formed on the connector 14 side. A secondary branching point is a branching point that is formed between primary branching points, and relative to which no branching points are formed on either primary branching point side.

Specifically, in the wire harness 10 shown in FIG. 2, the point where the branch lines 122 that extend from the trunk line 121 to the connectors 14a and 14b branch off (a branching position P1) and the point where the branch lines 122 that extend from the trunk line 121 to the connectors 14d, 14e, and 14f branch off (a branching position P2) are primary branching points. Also, in the wire harness 10 shown in FIG. 2, the point where the branch line 122 that extends from the trunk line 121 to the connector 14c branches off (a branching position P3) is a secondary branching point.

Note that there is the possibility of the wire harnesses 10 being only provided with primary branching points. There is also the possibility of three or more-ordinal branching points being provided.

### Connector Holding Part Supporting Device 20

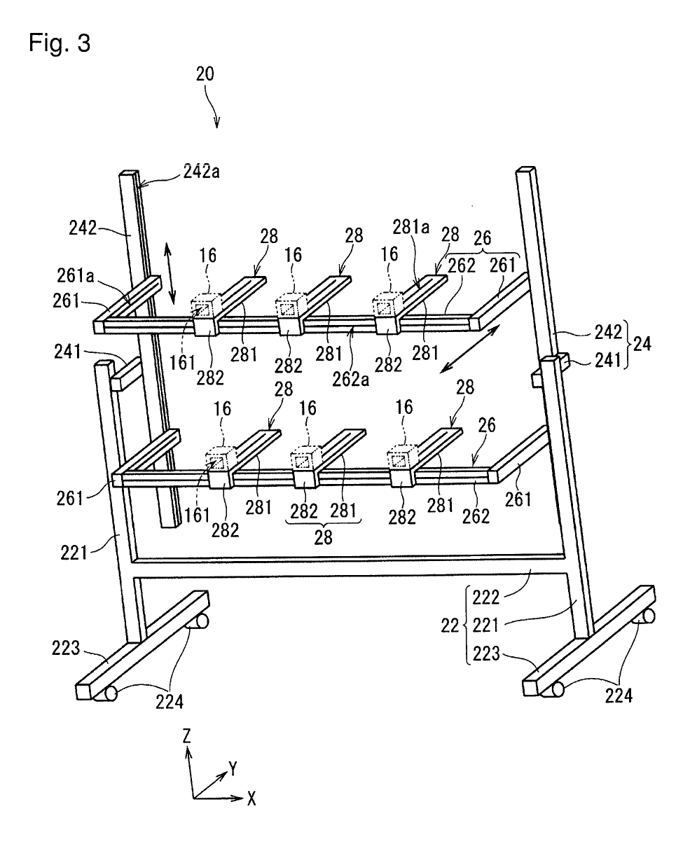

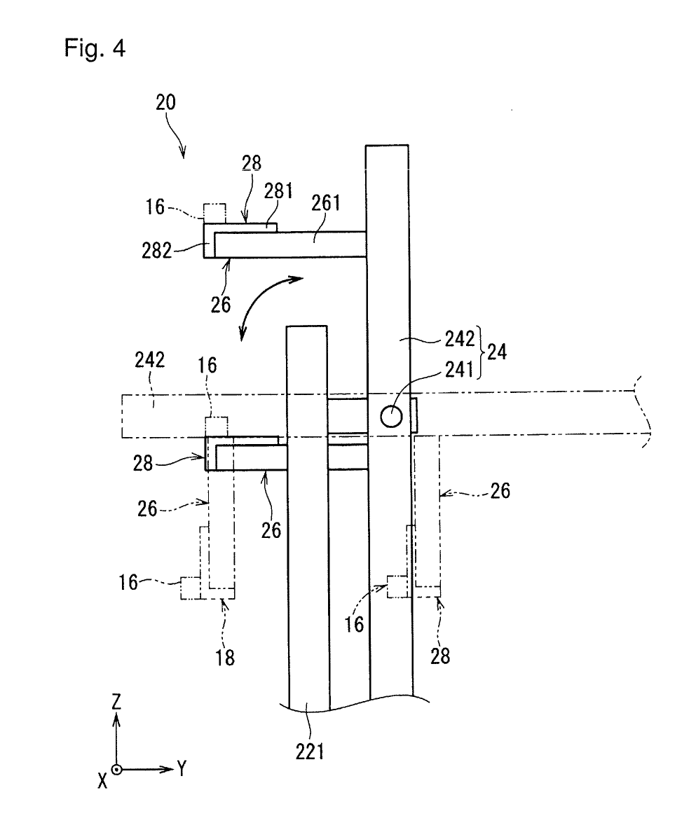

Next, the connector holding part supporting device 20 that holds the connector holding parts 16 will be described with reference to FIGS. 3 to 5 as well. FIG. 3 is a perspective view showing the connector holding part supporting device 20. FIG. 4 is a schematic side view showing the connector holding part supporting device 20. FIG. 5 is a diagram in which a part of FIG. 3 is enlarged. FIG. 5 shows that a connector 14 is supported by a connector holding part 16, and electrical wires 12 are inserted into the connector 14.

Here, the connector holding part supporting device 20 includes a plurality of supporting parts. The supporting parts are provided so as to be able to directly or indirectly support the plurality of connector holding parts 16 such that the electrical wires 12 extending from the connectors 14 that are held by the connector holding parts 16 dangle. The supporting parts are able to support a plurality of connector holding parts 16 so as to be arranged in a first direction that is orthogonal to the vertical direction, and the plurality of supporting parts are arranged in a second direction that is orthogonal to the first direction.

More specifically, the connector holding part supporting device 20 in this example includes a frame 22, connector bar attachment parts 24, and connector bars 26. The connector holding part supporting device 20 in this example further includes connector holding part attachment parts 28. Here, an example in which the connector bars 26 are the above-described supporting parts will be described.

The frame 22 is configured to support the connector bar attachment parts 24. More specifically, the frame 22 includes a pair of first rod-shaped portions 221, a second rod-shaped portion 222 that couples the pair of first rod-shaped portions 221 to each other, and third rod-shaped portions 223 that are respectively provided at end portions of the pair of first rod-shaped 221 on one side in the lengthwise direction. The first rod-shaped portions 221 extend in the vertical direction. The second rod-shaped portion 222 couples intermediate portions of the pair of first rod-shaped portions 221 in the lengthwise direction to each other, at positions that are closer to end portions of the first rod-shaped portions 221 on one side. The second rod-shaped portion 222 extends in a direction that is orthogonal to the lengthwise direction of the first rod-shaped portions 221. The third rod-shaped portions 223 extend from the edges of end portions of the first rod-shaped portions 221 on one side in the lengthwise direction, in a lateral direction that is orthogonal to the lengthwise direction of the first rod-shaped portions 221 and the lengthwise direction of the second rod-shaped portion 222. A pair of casters 224 are provided on the lower surface of each third rod-shaped portion 223. Thus, the connector holding part supporting device 20 is movable.

In the following description, for the sake of convenience, the direction in which the second rod-shaped portion 222 in FIG. 3 extends is referred to as an x axis direction, the direction in which the third rod-shaped portions 223 in FIG. 3 extend is referred to as a y axis direction, and the direction in which the first rod-shaped portions 221 in FIG. 3 extend is referred to as a z axis direction, in some cases. In this regard, in the following description, it is assumed that the z axis direction is a vertical direction, and the x axis direction and the y axis direction are horizontal directions.

The connector bar attachment parts 24 are attached to the frame 22, and are configured to support the connector bars 26. More specifically, each connector bar attachment part 24 includes a coupling portion 241 and a first rail portion 242.

The coupling portions 241 each have a short rod shape, and are respectively connected to the pair of first rod-shaped portions 221 at positions that are closer to end portions of the first rod-shaped portions 221 on the other side in the lengthwise direction. In this regard, the coupling portions 241 are coupled to the first rod-shaped portions 221 so as to protrude from the first rod-shaped portions 221 in a direction that intersects the lengthwise direction of the first rod-shaped portions 221 (the y axis direction).

The first rail portions 242 are respectively connected to edge side positions of the pair of coupling portions 241. In this example, intermediate portions of the first rails are attached to the coupling portions 241.

Also, the connector bar attachment parts 24 in this example are configured to be rotatable relative to the frame 22. More specifically, in this example, the coupling portions 241 and the first rail portions 242 are coupled to the frame 22 so as to be rotatable, as shown in FIG. 4. The range of rotation of the connector bar attachment parts 24 relative to the frame 22 may be determined as appropriate. Preferably, each first rail portion 242 can change orientation from a state in which the lengthwise direction of the first rail portion 242 is the vertical direction to a state in which the lengthwise direction is the horizontal direction.

The connector bars 26 are attached to the connector bar attachment parts 24, and are configured to support the connector holding parts 16. More specifically, each connector bar 26 in this example includes a second rail portion 261 and a third rail portion 262.

The second rail portions 261 each have a rod shape, and are respectively attached to the pair of first rail portions 242. In this example, side surfaces of end portions of the second rail portions 261 on one side in the lengthwise direction are attached to the first rail portions 242 such that the second rail portions 261 extend in a direction (the y axis direction in FIG. 2) that is orthogonal to the lengthwise direction of the first rail portions 242 and to the direction that connects the pair of first rail portions 242. In addition, the second rail portions 261 are provided so as to be able to change position relative to the first rail portions 242 in the lengthwise direction of the first rail portions 242. In this example, the second rail portions 261 are provided so as to be slidable relative to the first rail portions 242 in the lengthwise direction of the first rail portions 242. Note that a configuration that enables the second rail portion 261 to slide relative to the first rail portion 242, as well as configurations that enable other slidable members to slide, will be described later in detail.

Each third rail portion 262 has a rod shape, and both end portions thereof are attached to a pair of second rail portions 261 such that the third rail portion 262 is interposed between the pair of second rail portions 261. The third rail portions 262 extend in the x axis direction. Each third rail portion 262 is provided so as to be able to change position relative to the corresponding second rail portion 261 in the lengthwise direction of the second rail portion 261. In this example, each third rail portion 262 is provided so as to be slidable relative to the corresponding second rail portion 261 in the lengthwise direction of the second rail portion 261.

A plurality of connector bars 26 (two in this example) are provided in a direction (the z axis direction in FIG. 2) that is orthogonal to the lengthwise direction of the connector bars 26. In this example, two connector bars 26 are attached to the connector bar attachment parts 24. In this example, the two connector bars 26 are attached so as to bulge out toward the same side relative to the connector bar attachment parts 24, i.e. such that the second rail portions 261 protrude toward the same side (the negative side in the y axis direction in FIG. 2) relative to the first rail portions 242. However, this is not essential. The connector bars 26 may be attached so as to bulge toward opposite sides (the positive side and the negative side in the y axis direction in FIG. 2) relative to the connector 14 attachment parts.

It is preferable that the number of connector bars 26 is changeable. In this example, the connector bars 26 are detachably attached to the connector bar attachment parts 24. Hence, it is possible to change the number of connector bars 26 as appropriate according to the shape or the like of the wire harness that is to be manufactured.

The connector holding parts 16 are directly or indirectly attached to the connector bars 26. In the following description, it is assumed that the connector holding parts 16 are indirectly attached to the connector bars 26 via the connector holding part attachment parts 28.

The connector holding part attachment parts 28 are attached to the connector bars 26 so as to be slidable in the lengthwise direction (the x axis direction) of the connector bars 26 (the third rail portions 262). More specifically, each connector holding part attachment part 28 includes a fourth rail portion 281 and a protruding portion 282.

The fourth rail portion 281 has an elongated flat plate shape. A connector holding part 16 is attached to one main surface of the fourth rail portion 281. The other main surface of the fourth rail portion 281 is attached to a third rail portion 262 at an end portion on one side in the lengthwise direction.

The protruding portion 282 is formed so as to have a flat plate shape and protrude from the edge of an end portion of the fourth rail portion 281 on one side in the lengthwise direction of the fourth rail portion 281 toward the other main surface side of the fourth rail portion 28. Therefore, each connector holding part attachment part 28 has a substantially L-like shape in side view. A main surface that faces toward the other end portion of the fourth rail portion 281 out of the main surfaces of the protruding portion 282 is attached to a third rail portion 262.

The connector holding part attachment parts 28 are detachably attached to the connector bars 26.

### Connector Holding Parts

Here, the connector holding parts 16 that hold the connectors 14 will be described.

The connector holding parts 16 are configured to hold the connectors 14. More specifically, each connector holding part 16 in this example has a substantially rectangular parallelepiped shape, and a recessed portion 161, to which a connector 14 is to be fitted, is formed in one main surface. It is preferable that the inner surface of the recessed portion 161 has a shape that matches the outer surface of the connector 14 so that the connectors 14 can be precisely positioned. In this regard, it is preferable that the plurality of connector holding parts 16 are set as appropriate so as to match the shape of the connectors 14 that are to be held.

As described above, the connector holding parts 16 are directly or indirectly attached to the connector bars 26. In this regard, the connector holding parts 16 are attached to the connector bars 26 so as to be slidable in the lengthwise direction of the connector bars 26. This configuration makes it easier to adjust the relative positional relationship between the connectors 14. The connector holding part attachment parts 16 are detachably attached to the connector bars 26. Hence, it is possible to change the number of connector holding parts 16 as appropriate depending on the wire harness 10 that is to be manufactured. Also, it is possible to attach the connector holding parts 16 that match the shape of the connectors 14 depending on the wire harness 10 that is to be manufactured.

In this example, the connector holding parts 16 are indirectly attached to the connector bars 26 via the connector holding part attachment parts 28. That is, in this example, the connector holding part attachment parts 28 are attached to the connector bars 26 so as to be slidable in the lengthwise direction of the connector bars 26 (the x axis direction), and hence the connector holding parts 16 are slidable in the lengthwise direction of the connector bars 26 (the x axis direction). Also, the connector holding parts 16 are detachably attached to the connector holding part attachment parts 28, and hence the connector holding parts 16 are attachable to and detachable from the connector bars 26.

Also, in this example, the connector holding parts 16 are attached to the connector holding part attachment parts 28 so as to be slidable in a direction (the y axis direction in FIG. 2) that is orthogonal to the lengthwise direction of the connector bars 26. In this example, the connector holding parts 16 are attached to the fourth rail portions 281 so as to be slidable in the lengthwise direction of the fourth rail portions 281.

The following describes configurations that make it possible for members to be slidable relative to each other. Examples of configurations that make it possible for members to be slidable relative to each other include a configuration in which one of a pair of members that are slidable relative to each other is provided with a groove, and the other member is fitted into the groove and slides along the groove. In this regard, the other member may be directly attached to the one member so as to slide, or attached to the on member via another member so as to slide. Examples of the aforementioned other member include a slider member that is attachable to the other member, and is fitted to the groove so as to be slidable. In the following description, it is assumed that the members are slidable due to grooves being formed.

That is, each first rail portion 242 has a rod shape with a rectangular cross section, and a groove 242a that extends in the lengthwise direction of the first rail portion 242 (the z axis direction in FIG. 2) is formed in one side surface of the first rail portion 242 as a configuration that enables a second rail portion 261 to slide relative to the first rail portion 242. In this example, the groove 242a is formed in side surfaces of the pair of first rail portions 242 that face each other (side surfaces that face each other in the x axis direction), out of the side surfaces of the first rail portions 242. Portions of the second rail portions 261 are fitted into the grooves 242a, and slide along the grooves 242a.

Similarly, each second rail portion 261 has a rod shape with a rectangular cross section, and a groove 261a that extends in the lengthwise direction of the second rail portion 261 (the y axis direction in FIG. 2) is formed in one side surface of the second rail portion 261 as a configuration that enables a third rail portion 262 to slide relative to the second rail portion 261. In this example, the groove 261a is formed in side surfaces of each pair of second rail portions 261 that face each other (side surfaces that face each other in the x axis direction), out of the side surfaces of the second rail portions 261. Portions of the third rail portions 262 are fitted into the grooves 261a, and slide along the grooves 261a.

Also, each third rail portion 262 has a rod shape with a rectangular cross section, and a groove 262a that extends in the lengthwise direction of the third rail portion 262 (the x axis direction) is formed in two side surfaces of the third rail portion 262 as a configuration that enables a connector holding part attachment part 28 to slide relative to the third rail portion 262. In this example, when the first rail portions 242 are orientated in the vertical direction, out of the side surfaces of each third rail portion 262, the groove 262a is formed in a side surface that faces upward in the vertical direction and a side surface that faces toward the edge of a second rail in the horizontal direction. Portions of the connector holding part attachment parts 28 are fitted into the grooves 262a, and slide along the grooves 262a.

Also, a groove 281a that extends in the lengthwise direction of the fourth rail portions 281 (the y axis direction in FIG. 2) is formed in one main surface of each fourth rail portion 281 that has an elongated flat plate shape as a configuration that enables a connector holding part 16 to slide relative to the fourth rail portion 281. Portions of the connector holding parts 16 are fitted into the grooves 281a, and slide along the grooves 281a.

It is preferable that the members that slide relative to each other can be fixed at any position or predetermined position in the sliding path. For example, bolts and nuts can be employed as configurations that enable the members that slide relative to each other to be fixed at any position or predetermined position in the sliding path. That is, when a pair of members that slide relative to each other reach desired fixing positions, the members are fixed at the positions by fastening a bolt and a nut. When it is desired to enable a pair of members to slide relative to each other, the members can be enabled to slide by loosening a bolt and a nut. In this regard, for example, if the bolt hole is elongated as with the groove along the groove, the pair of members that slide relative to each other can be fixed at any position. Also, for example, a plurality of bolt holes are provided along the groove, the pair of members that slide relative to each other can be fixed at predetermined positions.

Of course, configurations that enable the members that slide relative to each other to be fixed at any position or predetermined position in the sliding path are not limited to bolts and nuts. For example, it is possible to employ a configuration in which one of a pair of members that slide relative each other is provided with an operation portion and a protrusion that retracts in synchronization with the operation portion. That is, when a pair of members are desired to slide relative to each other, it is possible to slide the members by operating the operation portion to retract the protrusion. When the pair of members that slide relative to each other reach desired fixing positions, the members can be fixed at the positions by allowing the protrusion to protrude.

### Connector Supporting Operation

The operation to make the connector holding part supporting device 20 support the connector holding parts 16 and making the connector holding parts 16 support the connectors 14 may be performed using a specific jig or the like, or with the operator's hand. In this regard, the operation to make the connector holding part supporting device 20 support the connector holding parts 16 and the operation to make the connector holding parts 16 support the connectors 14 may be performed one after the other, or at the same time.

In the following description, it is assumed that three or more connectors 14 that are connected to one primary branching point are two-dimensionally arranged when viewed in the direction in which electrical wires 12 are inserted. In this regard, it is preferable that the three or more connectors 14 are set in an arrangement that is similar to the relative positional relationship between the connectors 14 when mounted on a vehicle. This configuration makes it unnecessary to correct the relative positional relationship between three or more connectors 14 that are connected to the one primary branching point, after branches have been formed. As a result, it is possible to prevent electrical wires 12 from, for example, twisting when the relative positional relationship between three or more connectors 14 that are connected to the one primary branching point is corrected.

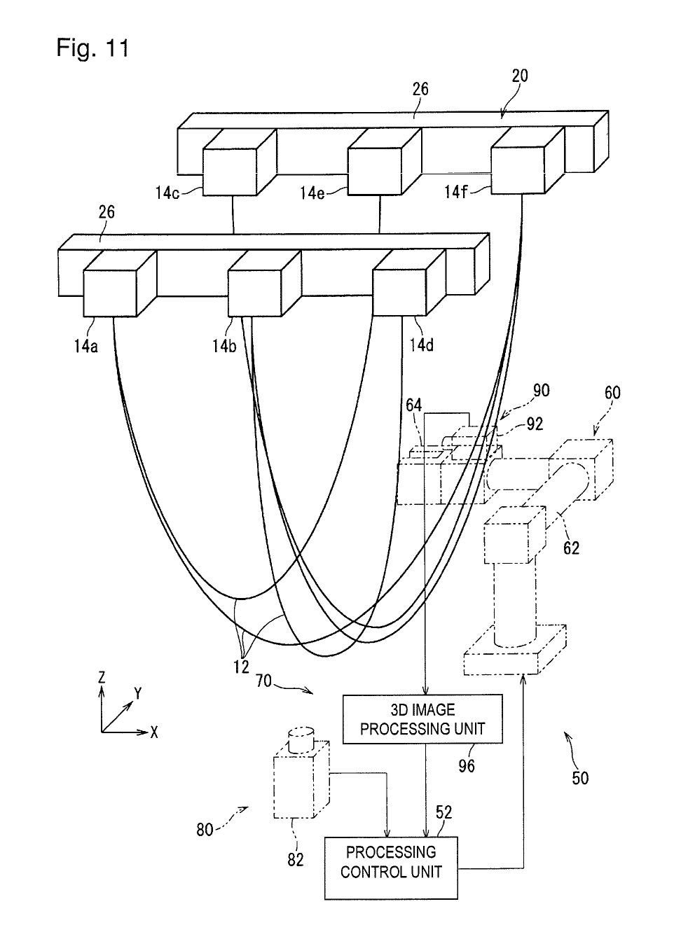

Specifically, as shown in FIG. 2, the connectors 14d, 14e, and 14f are connected to one primary branching point in this example. Two connectors 14 (the connectors 14e and 14f in this example) out of the three connectors 14d, 14e, and 14f are supported by one of the connector bars 26, and the remaining one connector 14 (the connector 14d in this example) is supported by another of the connector bars 26 (see FIG. 11). That is, in the connector holding part supporting device 20, the connector holding parts 16 that respectively support the connectors 14a, 14b, and 14d are supported by one of the connector bars 26, and the connector holding parts 16 that respectively support the connectors 14c, 14e, and 14f are supported by the other of the connector bars 26.

Of course, the arrangement of the connectors 14 is not limited to the above-described arrangement. For example, as in the modification described below, three or more connectors 14 that are connected to one primary branching point may be one-dimensionally arranged when viewed in the direction in which electrical wires 12 are inserted. Also, even if the connectors 14 are arranged in the above-described arrangement, the connectors 14 need only be in the above-described arrangement when branches are formed, and are not necessarily in the above-described arrangement when electrical wires are inserted. That is, for example, the connectors 14 when electrical wires are inserted may be set in an arrangement in which the electrical wires 12 are unlikely to become tangled, and rearranged in the above-described arrangement after electrical wires have been inserted.

The above-described connector holding part supporting device 20 to which the connector holding parts 16 are attached is transported to the electrical wire inserting device 30. Then, the electrical wire inserting device 30 inserts the electrical wires 12 into the connectors 14 that are attached to the connector holding part supporting device 20.

### Electrical Wire Inserting Device 30

Next, the electrical wire inserting device 30 that inserts the electrical wires 12 into the connectors 14 will be described with reference to FIG. 6. FIG. 6 is a schematic perspective view showing the electrical wire inserting device 30.

In the following description, it is assumed that the electrical wire inserting device 30 inserts the electrical wires 12 upward in the vertical direction from the lower side in the vertical direction. Therefore, the connectors 14 are supported by the connector holding part supporting device 20 such that the openings of the cavities 141 face downward in the vertical direction. In this example, as indicated by the imaginary lines (two-dot chain lines) in FIG. 4, the connector holding part supporting device 20 is orientated such that the lengthwise direction of the first rail portions 242 coincides with the horizontal direction, and thus the connectors 14 attached to the connector holding part supporting device 20 face downward in the vertical direction. In this regard, it is preferable that the connectors 14 are collected at one position relative to each connector bar 26 as shown in FIG. 6. This makes it easier to insert the electrical wires 12 using an automatic machine.

Specifically, the electrical wire inserting device 30 includes an electrical wire inserting mechanism 32 and an electrical wire fixing mechanism 40. Although the electrical wire inserting mechanism 32 and the electrical wire fixing mechanism 40 in the present embodiment are provided in a mode where they are built into one supporting member 48, the present invention is not limited to such a mode.

The electrical wire fixing mechanism 40 includes an electrical wire fixing portion 42 that fixes the electrical wires 12 and a moving mechanism 44 that moves the electrical wire fixing portion 42.

The moving mechanism 44 is constituted by a liner motor, a linear driving mechanism that includes a screw shaft, a motor that is driven to rotate the screw shaft, and a nut portion that is screwed onto the screw shaft, or a linear actuator such as an air cylinder or a hydraulic cylinder. The moving mechanism 44 extends in a substantially horizontal direction, and includes a first driving portion 44a that supports the electrical wire fixing portion 42, and a second driving portion 44b that extends in a direction that is orthogonal to the first driving portion 44a.

The electrical wire fixing portion 42 is moved by the first driving portion 44a in the direction in which the first driving portion 44a extends (the x axis direction in this example). The second driving portion 44b extends in a substantially vertical direction that is orthogonal to the first driving portion 44a (the z axis direction in this example).

The second driving portion 44b is provided at an end portion of the first driving portion 44a, and moves the first driving portion 44a in the direction in which the second driving portion 44b extends (the y axis direction in this example). Note that a second driving portion 44b may be provided at both end portions of the first driving portion 44a. If this is the case, the second driving portions 44b drive in synchronization with each other, and are controlled so as to keep the relationship in which the direction in which the first driving portion 44a extends and the direction in which the second driving portions 44b extend are orthogonal to each other.

The above-described configurations enable the electrical wire fixing portion 42 that fixes the electrical wires 12 to move in the x axis direction and the z axis direction. If a third driving portion that extends in the y axis direction is additionally provided at an end portion of the second driving portion 44b, the electrical wire fixing portion 42 can move in the y axis as well. In the present embodiment, a second driving portion 36c of the electrical wire inserting mechanism 32 described below can be also used as the third driving portion.

The electrical wire fixing portion 42 usually fixes a plurality of electrical wires 12 to a side surface that faces a substantially horizontal direction. Specific examples of the configuration of the electrical wire fixing portion 42 include a configuration that includes, on the side surface that fixes the electrical wires 12, an elastic member in which grooves that each have a width that is sufficient to sandwich an electrical wire 12 are formed. The electrical wires 12 are fixed in the electrical wire fixing portion 42 so as to dangle downward in a substantially vertical direction.

The electrical wire inserting mechanism 32 includes an electrical wire inserting portion 34 that inserts electrical wires 12, and a moving mechanism 36 that moves the electrical wire inserting portion 34.

The moving mechanism 36 is constituted by a linear actuator as with that described above. The moving mechanism 36 includes a first driving portion 36a that extends in a substantially horizontal direction, a movable portion 36b that is supported by the first driving portion 36a, and a second driving portion 36c that extends in a direction that is orthogonal to the first driving portion 36a.

The movable portion 36b is moved by the first driving portion 36a in the direction in which the first driving portion 36a extends (i.e. the x axis direction). The second driving portion 36c extends in a substantially horizontal direction that is orthogonal to the first driving portion 36a (i.e. the y axis direction).

The second driving portion 36c is provided at an end portion of the first driving portion 36a, and moves the first driving portion 36a in the direction in which the second driving portion 36c extends. Note that a second driving portion 36c may be provided at both end portions of the first driving portion 36a. If this is the case, the second driving portions 36c drive in synchronization with each other, and are controlled so as to keep the relationship in which the direction in which the first driving portion 36a extends and the direction in which the second driving portions 36c extend are orthogonal to each other.

The movable portion 36b includes a first movable portion 361 that is supported by the first driving portion 36a, and a second movable portion 362 that is supported by the first movable portion 361.

The second movable portion 362 is provided on, for example, a side surface of the first movable portion 361 that faces in a substantially horizontal direction. The second movable portion 362 is movable in the y axis direction relative to the first movable portion 361. The movement is realized using, for example, a linear actuator that is mounted on the first movable portion 361.

The electrical wire inserting portion 34 is provided on, for example, the surface of the second movable portion 362 that is opposite the surface that is supported by the first movable portion 361. The electrical wire inserting portion 34 is movable in the z axis direction relative to the second movable portion 362. The movement is realized using, for example, a linear actuator that is mounted on the second movable portion 362.

The electrical wire inserting portion 34 is supported by the second movable portion 362, and includes an arm portion 34a that extends in the y axis direction, and grip portions 34b that are provided at an end portion of the arm portion 34a. The grip portions 34b are a pair of rod-shaped members, for example, and can be driven such that at least one of them moves closer to or away from the other.

The above-described configurations enable the electrical wire inserting portion 34 that inserts the electrical wires 12 to move in the x axis direction, the y axis direction, and the z axis direction.

Although the electrical wire inserting mechanism 32 and the electrical wire fixing mechanism 40 in the present embodiment move in the x, y or z axis direction for the sake of convenience, these directions are merely examples, and the directions of movement are not limited to these directions. That is, it suffices if the mechanisms can move in a three-dimensional space, and, for example, there are cases in which the directions of movement are defined without using an orthogonal coordinate system, and cases in which different directions of movement are defined for each mechanism.

The electrical wire inserting device 30 according to the present embodiment also includes an insertion control unit 31 that controls operations of the entire device. The insertion control unit 31 is constituted by a typical microcomputer that includes a CPU, a ROM, a RAM, and so on, and is connected to the driving units of the device. The insertion control unit 31 is configured to control operations, which include an operation to insert the electrical wires 12 described below, according to a software program that is stored therein in advance.

### Electrical Wire Inserting Operation

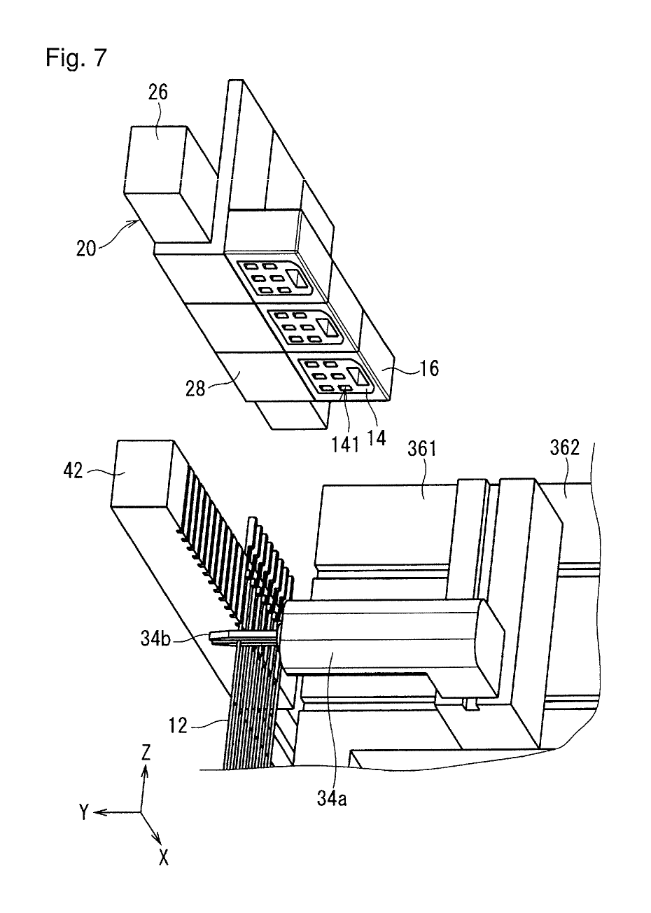

Next, operations of the electrical wire inserting device 30 according to the present embodiment will be described with reference to FIGS. 7 to 10 in addition to FIG. 6. FIGS. 7 to 10 illustrate operations performed by the electrical wire inserting device 30 according to the present embodiment to insert the electrical wires 12. It is assumed that the operations described below are performed by the driving units, which include linear actuators, being controlled by the above-described insertion control unit.

First, an electrical wire 12 is fixed to a side surface of the electrical wire fixing portion 42, and the connector holding part supporting device 20, to which the connectors 14 are attached, is set to a predetermined position relative to the electrical wire inserting device 30. The electrical wire 12 may be fixed to the electrical wire fixing portion 42 using a specific jig or the like, or with the operator's hand. As shown in FIG. 6, the electrical wire 12 is fixed to the electrical wire fixing portion 42 so as to dangle downward in a substantially vertical direction. Also, since the connector holding part supporting device 20 has been set to a predetermined position relative to the electrical wire inserting device 30, the main surfaces of the connectors 14 are supported so as to face downward relative to the horizontal direction, and therefore the openings of the cavities 141 in the main surfaces of the connectors 14 face downward relative to the horizontal direction.

Next, the grip portions 34b of the electrical wire inserting portion 34 grip an end portion of the electrical wire 12 that is fixed to the electrical wire fixing portion 42. To perform this operation, first, the first driving portion 36a and the second driving portion 36c are driven to move the electrical wire inserting portion 34 to a position in the x-y plane at which the electrical wire fixing portion 42 is located. In this regard, the moving mechanism 44 may be driven to move the electrical wire fixing portion 42. Furthermore, fine adjustment is performed by driving the linear actuator mounted on the first movable portion 361 and the linear actuator mounted on the second movable portion 362, and thus the grip portions 34b of the electrical wire inserting portion 34 are moved to positions at which the grip portions 34b can grip the electrical wire 12 fixed to the electrical wire fixing portion 42. In this state, the pair of grip portions 34b are driven so as to be close to each other, and thus the grip portions 34b grip the end portion of the electrical wire 12 as shown in FIG. 7. The electrical wire 12 thus gripped is held so as to dangle downward in a substantially vertical direction from the gripped position.

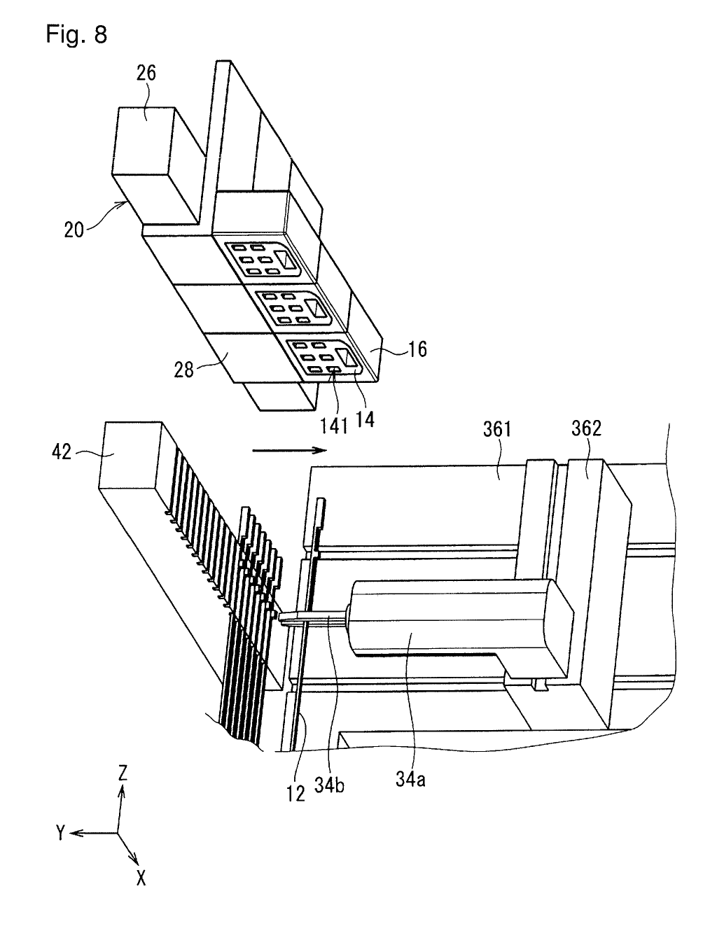

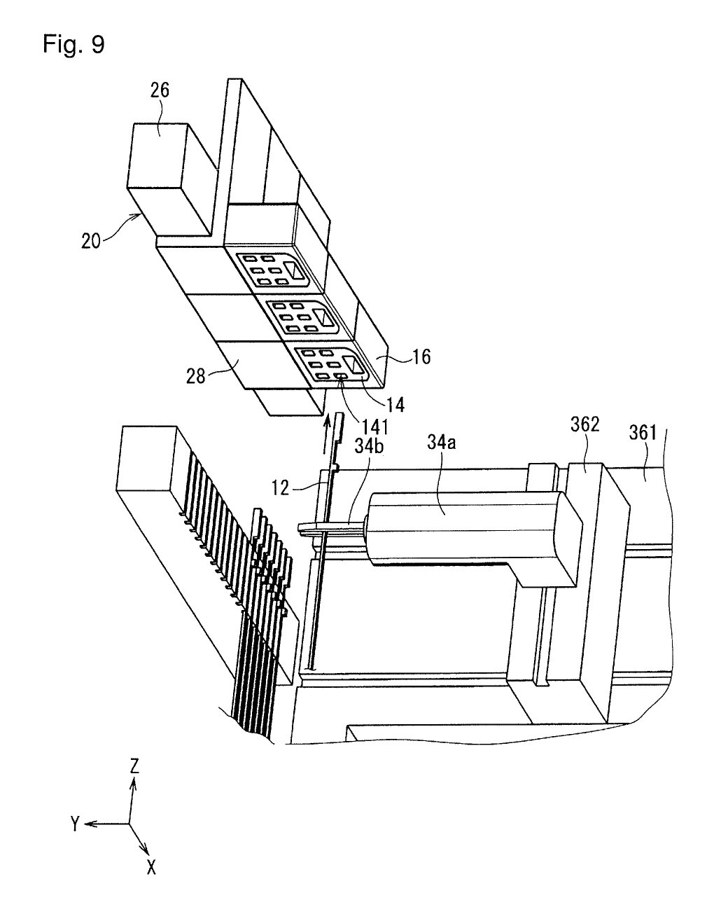

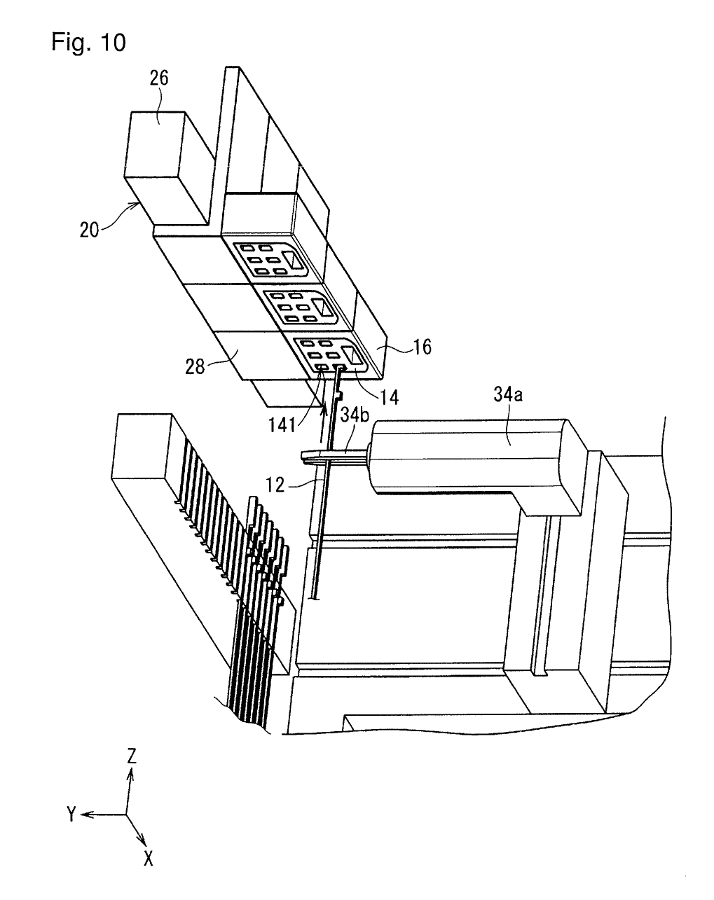

Next, as shown in FIG. 8 as well as in FIG. 9, the moving mechanism 36 that moves the electrical wire inserting portion 34 is driven, and thus an end portion above, in the vertical direction, of the electrical wire 12 that is gripped by the grip portions 34b is located forward of the opening of an cavity 141 that is provided in a connector 14. Next, as shown in FIG. 10, the linear actuator mounted on the second movable portion 362 is mainly driven, and thus the end portion of the electrical wire 12 is inserted into the opening of the cavity 141. At this time, the arm portion 34a and the grip portions 34b of the electrical wire inserting portion 34 are moved such that the electrical wire 12 is inserted into the cavity 141 in the depth direction of the cavity 141. For example, if the main surface of the connector 14 faces downward in the vertical direction, the arm portion 34a and the grip portions 34b of the electrical wire inserting portion 34 should be moved in the z axis direction. The electrical wire 12 gripped by the grip portions 34b is inserted into the cavity 141 through such operations.

The above-described operations are repeated, and thus the electrical wires 12 can be sequentially inserted into the plurality of cavities 141. Upon the predetermined electrical wires 12 being inserted into the connectors 14 that are attached to the connector holding part supporting device 20, the connector holding part supporting device 20 is transported to the electrical wire group processing device 50. The electrical wire group processing device 50 forms branches from the electrical wires 12 that dangle from the connectors 14.

### Electrical Wire Group Processing Device 50

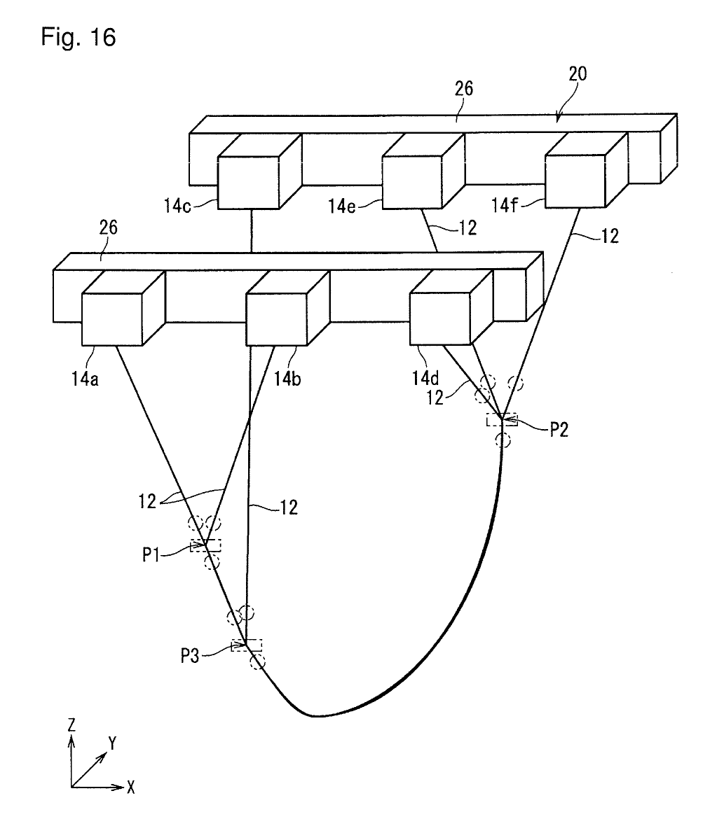

Next, the electrical wire group processing device 50 that forms branches from the electrical wires 12 that dangle from the connectors 14 will be described with reference to FIG. 11. FIG. 11 is a schematic view showing the electrical wire group processing device 50. Note that the connector holding parts 16 and the connector holding part attachment parts 28 are omitted from FIGS. 11 to 18.

The electrical wire group processing device 50 includes a processing robot 60, a processing control unit 52, and an image acquisition system 70.

The processing robot 60 is a typical industrial robot. FIG. 11 shows a typical vertically multi-jointed robot. The processing robot 60 includes a robot arm 62 and a processing operation unit 64 that is provided at a leading end portion of the robot arm 62. The robot arm 62 has a configuration in which a plurality of arm portions are coupled to each other with joint mechanisms therebetween so as to be rotatable about their respective shafts The processing operation unit 64 is provided at a leading end portion of the robot arm 62. The processing robot 60 operates the robot arm 62 to move the processing operation unit 64 to any positions relative to the connector holding part supporting device 20 installed to the electrical wire group processing device 50, in any orientation.

The processing operation unit 64 performs processing including processing for forming branches from the electrical wires 12. In this example, the processing operation unit 64 performs, as processing for forming branches, processing for collecting portions of electrical wires 12 at predetermined positions in the direction in which the electrical wires 12 extend, to a certain position (bundling up intermediate portions of a plurality of electrical wires 12 in the direction in which the electrical wires 12 extend), and processing for keeping the electrical wires 12 in the collected state. In this example, it is assumed that processing for tying a plurality of electrical wires 12 together (e.g. winding an adhesive tape therearound) is performed as processing for maintaining the electrical wires 12 in the collected state.

To perform the former process, a known robot hand that can grip and move an electrical wire 12 to a certain position, and that can grip and collect a plurality of electrical wires 12 can be used as the processing operation unit 64. To perform the latter process, a known automatic tape winder can be used as the processing operation unit 64.

In order to perform a plurality of types of processing operations, a plurality of processing robots 60 may be provided. Alternatively, a plurality of processing operation units 64 may be provided at a leading end of the robot arm 62 so as to be movable relative to each other.

Note that the processing robot may be a vertically multi-jointed robot, a rectangular coordinate type robot, or the like. The processing operation unit is changed as appropriate according to the operation that is to be performed on the electrical wires 12.

The processing control unit 52 is constituted by a typical computer that includes a CPU, a RAM, a ROM, an input circuit unit, and so on. The ROM is constituted by, for example, a rewritable non-volatile semiconductor memory such as a flash memory, and stores therein, for example, programs that describe procedures for determining the area to be processed and the position, orientation, and so on of the objects to be processed (electrical wires 12) based on image data that has been acquired by the image acquisition system 70, and processing procedures and the details of the processes that are to be performed on the electrical wires 12. The CPU executes the programs that are stored in the ROM, thereby performing processes to provide the processing robot 60 with various instructions, to perform various processes on the electrical wires 12 based on the image data acquired by the image acquisition system 70.

The image acquisition system 70 is a system for acquiring image data that is used to recognize the electrical wires 12 that constitute the above-described wire harness 10, and includes a two-dimensional vision system 80, which is a first vision system, and a three-dimensional vision system 90, which is a second vision system.

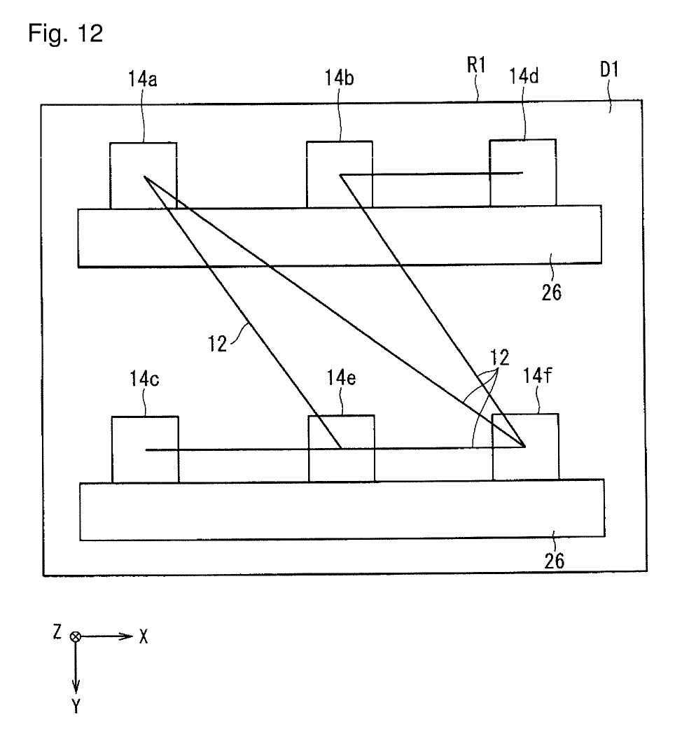

The two-dimensional vision system 80 is configured to acquire first image data D1 that is used to recognize the electrical wires 12 that constitute the wire harness 10, within a first image capturing range R1 (see FIG. 12).

That is, the two-dimensional vision system 80 includes a two-dimensional camera 82. The two-dimensional camera 82 is supported by a camera supporting member or the like, at a distance from the connector holding parts 16, for example, on a frame 22 of the connector holding part supporting device 20, and is provided so as to be able to capture images of the entire area of the connector holding part supporting device 20, in which the electrical wires 12 are expected be provided, as the first image capturing range R1. The first image data D1 acquired by the two-dimensional vision system 80 is given to the processing control unit 52.

Note that the two-dimensional vision system 80 may be provided with a plurality of two-dimensional cameras that each can capture images of a portion of the first image capturing range R1, and the first image data D1 of the first image capturing range R1 may be acquired by combining the images captured by the plurality of two-dimensional cameras. Also, the two-dimensional vision system 80 may include one two-dimensional camera that can capture images of a portion of the first image capturing range R1, and a moving mechanism unit that can be driven to move the two-dimensional camera, and may acquire the first image data D1 of the first image capturing range R1 by moving the two-dimensional camera to capturing a plurality of images of portions of the first image capturing range R1, and combining the plurality of images. Also, a three-dimensional vision system that acquires three-dimensional image data may be used as the first vision system.

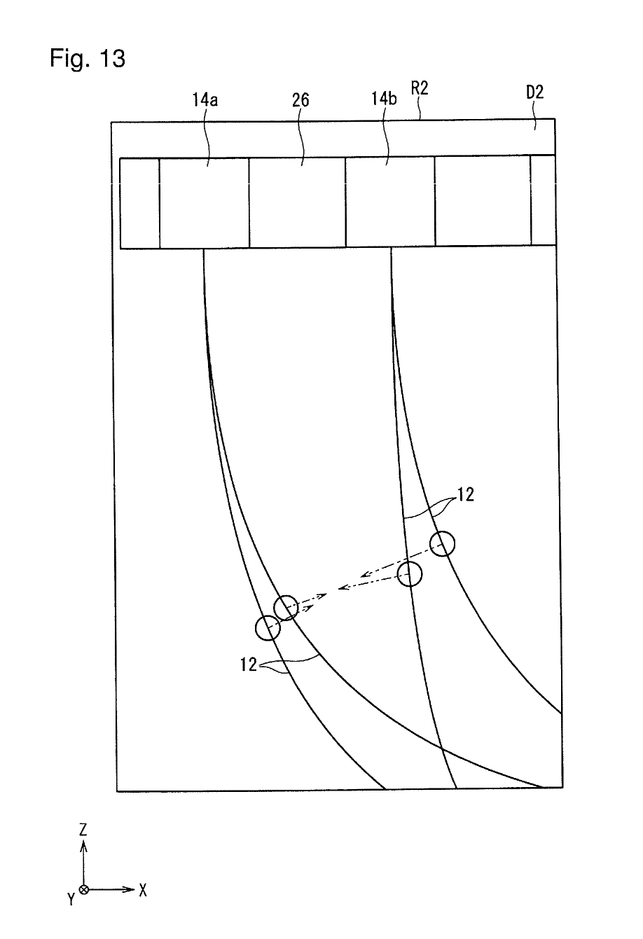

The three-dimensional vision system 90 is configured to acquire, regarding the electrical wires 12 that constitute the wire harness 10, second image data D2 that has a greater amount of information per unit area compared to the first image data D1, within a second image capturing range R2 that overlaps the first image capturing range R1 and is smaller than the first image capturing range R1 (see FIGS. 12 and 13).

In this example, the three-dimensional vision system 90 includes a stereo camera 92 that includes a plurality of cameras, and a three-dimensional image processing unit 96. The image capturing range of the stereo camera 92 is smaller than the above-described first image capturing range R1. The stereo camera 92 is attached to a leading end portion of the robot arm 62 of the processing robot 60, at a position where the stereo camera 92 does not interfere with the processing operation unit 64. Therefore, the stereo camera 92 can capture an image of the electrical wires 12 within the second image capturing range R2 that overlaps the first image capturing range R1 and is smaller than the first image capturing range R1.

Note that the stereo camera 92 may be provided so as to be movable relative to the connector holding part supporting device 20 using a moving mechanism unit that is separate from the processing robot 60.

The stereo camera 92 captures images of the second image capturing range R2 from different directions, and outputs the image data thus obtained to the three-dimensional image processing unit 96. The three-dimensional image processing unit 96 is constituted by a typical computer that includes a CPU, a RAM, a ROM, an input circuit unit, and so on. The ROM is constituted by, for example, a rewritable non-volatile semiconductor memory such as a flash memory, and stores therein, for example, programs that describe procedures for generating three-dimensional data (point group data) of the electrical wires 12 that are to be processed, as the second image data D2, based on a plurality of pieces of image data obtained by capturing images of the second image capturing range R2 from different directions. Then, the second image data D2 thus obtained by the three-dimensional image processing unit 96 is output to the processing control unit 52. Various kinds of known processing for generating three-dimensional point group data based on a plurality of pieces of image data obtained from different positions, using the principles of triangulation, may be employed as processing for generating three-dimensional data based on images obtained by the stereo camera 92. Note that the stereo camera 92 does not necessarily have a plurality of cameras, and may be configured to obtain a plurality of pieces of image data in different directions by moving one camera.

The second image data D2, which is the above-described three-dimensional data, has a greater amount of information per unit area compared to the above-described first image data D1. Here, the amount of information per unit area indicates the electrical wires 12 when the electrical wires 12 that extend from the connectors 14 that are supported by the connector holding part supporting device 20 are observed in a certain direction. For example, the following two cases can be conceived. The first case is, as described in the present embodiment, the case where the first vision system acquires two-dimensional image data as the first image data D1, and the second vision system acquires three-dimensional image data as the second image data D2. The second case is the case where, even if the first vision system acquires two-dimensional data or three-dimensional data as the first image data D1, and the second vision system acquires two-dimensional data or three-dimensional data, which is the same as the first image data D1 in terms of dimension, the latter second image data D2 has a higher resolution than the former first image data D1.

### Branch Forming Operation

The following more specifically describes an example in which the electrical wire group processing device 50 forms branches from the electrical wires 12.

First, in the initial state, as shown in FIG. 11, the connectors 14 to which end portions of the electrical wires 12 are connected are supported by the connector holding parts 16 attached to the connector holding part supporting device 20. The electrical wires 12 between the connectors 14 each dangle in a U-like shape. In this regard, as described above, the orientations of the connector bars 26 in this example are set such that the openings of the cavities 141 of the connectors 14 face downward in the vertical direction.

In this state, the two-dimensional vision system 80 acquires the first image data D1 of the first image capturing range R1 that includes the electrical wires 12, as shown in FIG. 12. In this example, it is assumed that the first image data D1 is captured from a position that is downward in the vertical direction. The first image data D1 thus acquired includes the electrical wires 12 that extend from the connectors 14 along a horizontal plane.

Here, it is assumed that processing for forming branches from the electrical wires 12 that extend from the connectors 14a and 14b, at positions that are at a certain distance from the connectors 14a and 14b (positions that correspond to the branching position P1), has been defined as the first processing that is to be performed on the electrical wires 12. Since the connectors 14 are supported by the connector holding part supporting device 20, they can be treated as being located at known positions.

In this case, the electrical wires 12 are recognized by performing image processing such as edge extraction processing on the first image data D1, and the second image capturing range R2 is determined so as to include portions of the electrical wires 12 that extend from the connector 14a and the connector 14b, the portions being located within the above-described distance. Thus, the area to be processed (the second image capturing range R2) can be determined within the first image capturing range R1. Note that recognition processing on the first image data D1 such as edge extraction processing may be performed by a two-dimensional image processing unit that is provided outside the processing control unit 52 and between the processing control unit 52 and the two-dimensional camera 82. If this is the case, a configuration that includes the two-dimensional camera 82 and the two-dimensional image processing unit may be regarded as the two-dimensional vision system.

Thereafter, the robot arm 62 of the processing robot 60 moves the stereo camera 92 to a position at which the stereo camera 92 can capture images of the second image capturing range R2. Then, the three-dimensional vision system 90 that includes the stereo camera 92 acquires the second image data D2 of the second image capturing range R2 as shown in FIG. 12. Note that the second image data D2 in FIG. 12 shows one mode of display of the second image data that two-dimensionally represents the second image capturing range R2 that is acquired as three-dimensional data.

Then, the routes of the electrical wires 12 with reference to the position of the connector 14a (14b), which is at a known position, are tracked based on the second image data D2, and positions that are at the above-described certain distance from the connector 14a (14b) (the positions in circles in FIG. 13) are specified. Portions at these positions are to be bundled up so as to form a branching point. Since the second image data D2 is three-dimensional data, the positions of the electrical wires 12 in the y axis direction in FIG. 12 can be also specified. Then, an instruction to collect the portions of the electrical wires 12 at the above-described positions to one position is given to the processing robot 60. In this case, the portions of the electrical wires 12 at the above-described positions may be collected to one position using separate robot hands. Alternatively, the plurality of electrical wires 12 may be collected to one position using one robot hand. Even in the latter case, it is possible to collect the portions of the electrical wires 12 at the above-described positions can be collected to one position by adjusting the position at which the connector 14a (14b) is supported and pulling out the electrical wires 12 from the connectors 14a (14b) and bundling up the electrical wires 12.

Thereafter, the collected state of the electrical wires 12, in which the electrical wires 12 extend from the positions to which the electrical wires 12 are collected, is kept. In this example, the electrical wires 12 are tied together as described above in order to maintain the collected state. That is, since the one position to which the electrical wires 12 are collected is a known position to which the electrical wires 12 have been moved by the robot hand, portions that extend from the position to the connectors 14a and 14b and portions that extend below the connectors 14a and 14b are tied together. The task of tying can be performed using an automatic tape winder attached to the robot arm 62 as described above.

When this task of tying is performed, the positions or the like of the electrical wires 12 are different from those when the entire image was captured, and therefore it is preferable that the second image data is captured again using the three-dimensional vision system 90, and the positions to be processed or the like are specified again using the second image data.

Note that if branches from the connectors 14 that are attached to one or more connector bars 26 out of the plurality of connector bars 26 are formed, the other connector bars 26 to which connectors 14 that are not relevant to the formation of branches may have been moved to positions at which the other connector bars 26 are unlikely to hinder the formation of branches.

For example, if branches from electrical wires that extend from the connectors 14a and 14b are formed, the connector bar 26 (the third rail portion 262) to which the connectors 14c, 14e, and 14f are attached may have been moved to a position that is at a distance in a downward direction from the connector bar 26 (the third rail portion 262) to which the connectors 14a and 14b are attached. Such movement can be realized by sliding the third rail portion 262 relative to the second rail portion 261.

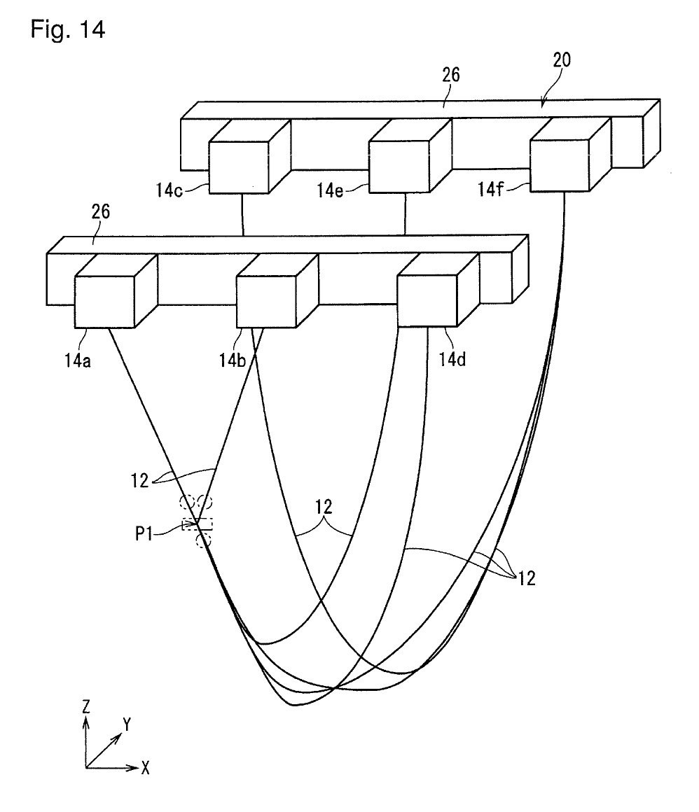

The state after this process is as shown in FIG. 14. In FIG. 14, a branching point is indicated by a square that is drawn with a two-dot chain line, and portions that are tied together are indicated by circles that are drawn with two-dot chain lines.

Subsequently, branches from the plurality of electrical wires 12 that extend from the remaining connectors 14 are also formed in the same manner as described above. In this example, branches are formed at predetermined positions (positions corresponding to the branching position P2) of the plurality of electrical wires 12 that extend from the connector 14d, the connector 14e, and the connector 14f.

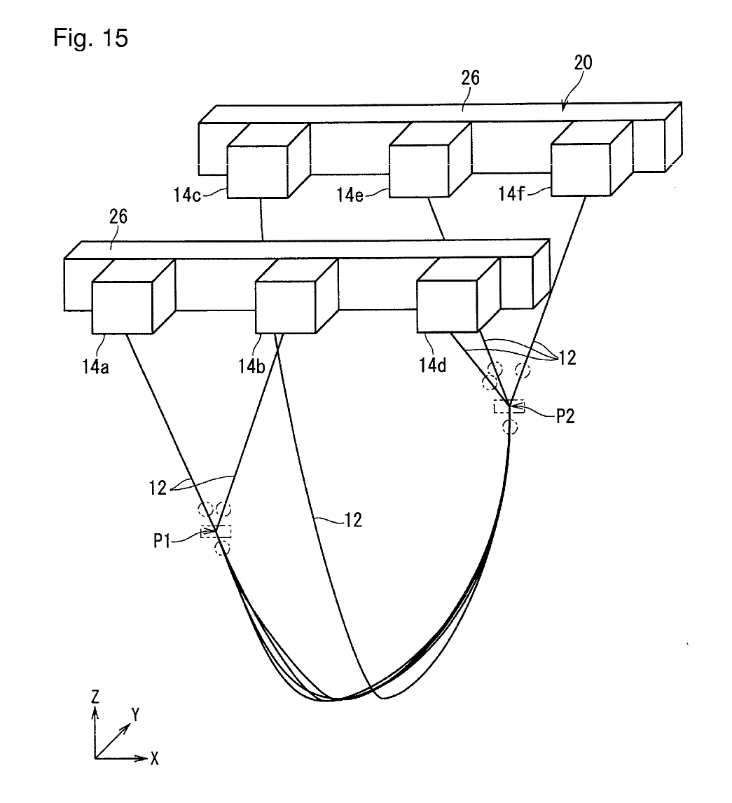

As a result, as shown in FIG. 15, branching points are formed in the plurality of electrical wires 12 that extend from the connectors 14a, 14b, 14d, 14e, and 14f, at the branching positions P1 and P2 that are close to the connectors 14a, 14b, 14d, 14e, and 14f.

Subsequently, branches from the plurality of electrical wires 12 are formed between the branching positions P1 and P2 that have been formed. In this example, the task of forming branches from the plurality of electrical wires 12 is performed such that electrical wires 12 that extend from the trunk line 121 that is a bundle of a large number of electrical wires 12 are connected to the connector 14c.

Again, the first image data is acquired first using the two-dimensional vision system 80, the electrical wires 12 are recognized by performing image processing such as edge extraction processing on the first image data, and the second image capturing range is determined so as to include portions of the electrical wires 12 that extend from the branching position P1 or P2 and portions of the electrical wires 12 that extend from the connector 14c, the portions being located within a certain distance, depending on the details of the subsequent process (e.g. which portion out of the electrical wires 12 between the branching positions P1 and P2 should be tied together).

Thereafter, the robot arm 62 of the processing robot 60 moves the stereo camera 92 to a position at which the stereo camera 92 can capture images of the second image capturing range. Then, the three-dimensional vision system 90 that includes the stereo camera 92 acquires the second image data of the second image capturing range.

Then, the routes of the electrical wires 12 with reference to the position of the connector 14c and the already-formed branching positions P1 and P2 (the branching positions P1 and P2 are specified as known positions or positions to which the electrical wires 12 are collected from a plurality of positions in the second image data D2) are tracked based on the second image data, and positions that are at a certain distance from the connector 14c and positions that are at a certain distance from the already-formed branching positions P1 and P2 in any direction are specified. Portions at these positions are to be bundled up in the trunk line 121. Then, an instruction to collect the portions of the electrical wires 12 at the above-described positions to one position using the processing robot 60 is given. Thereafter, portions of the electrical wires 12 around the above-described positions, at which the electrical wires are bundled up, are tied together.

As a result of the plurality of electrical wires 12 being bundled at positions between the branching positions P1 and P2, as shown in FIG. 15, the plurality of electrical wires 12 are divided into branches at the plurality of branching positions P1, P2 and P3, and are tied together. Thus, the wire harness 10 can be manufactured.

If necessary, it is possible to attach a clamp part for fixing the wire harness 10 to a vehicle, a protector for protecting the wire harness 10, an exterior part such as a corrugated tube, and the like may be attached to the wire harness 10 using the processing robot 60 or by hand.

According to the above-described wire harness manufacturing method, the plurality of connectors 14 into which the electrical wires 12 are inserted are held by the connector holding parts 16 such that the electrical wires 12 dangle, and branches from portions dangling from the connectors 14, of the electrical wires 12 are formed, with the connectors 14 remaining in the state of being held by the connector holding parts 16. Therefore, it is possible to perform branch formation on a semi-finished product in which the electrical wires 12 have been inserted into the connectors 14, without placing the semi-finished product on a jig board. In this regard, since the supporting parts that can support the plurality of connector holding parts 16 in the first direction that is orthogonal to the vertical direction are arranged in the second direction that is orthogonal to the first direction, the method is applicable to a wide variety of branch shapes.

Also, since the plurality of connector holding parts 16 are arranged so as to be movable relative to each other, it is easier to adjust the relative positional relationship between the connectors 14. In particular, for example, when forming branches, it is possible to arrange the connectors 14 in an arrangement that is more similar to the arrangement in a vehicle. Consequently, it is possible to obtain a wire harness 10 that has a shape that is more similar to the shape of the wire harness 10 when mounted on a vehicle.

In particular, when inserting electrical wires, it is preferable that the connectors 14 are as close as possible to each other, from the viewpoint of making insertion easier, or improving the efficiency of insertion. On the other hand, when forming branches, it is preferable that the connectors 14 are arranged as dispersedly as possible, from the viewpoint of the diversity of manufacturable wire harnesses. In this way, the insertion of electrical wires and the formation of branches, which are required to satisfy contradictory conditions regarding the relative positions of the connectors 14, can be performed using the same connector holding part supporting device 20 due to the connector holding parts 16 being movable relative to each other.

Also, since the connector holding parts 16 can be directly or indirectly attached to the rod-shaped connector bars 26 so as to be slidable in the lengthwise direction of the connector bars 26, it is easier to adjust the relative positional relationship between the connectors 14. Also, since a plurality of connector bars 26 are arranged in a direction that is orthogonal to the lengthwise direction thereof, it is possible to two-dimensionally arrange the connector holding parts 16 when viewed from the direction in which the electrical wires are inserted. Consequently, it is possible to obtain a wire harness 10 that has a shape that is more similar to the shape of the wire harness 10 when mounted on a vehicle.

Also, since the connector holding parts 16 are attached to the connector holding part attachment parts 28 that are attached to the connector bars 26 so as to be slidable in the lengthwise direction of the connector bars 26, so as to be slidable in a direction that is orthogonal to the lengthwise direction of the connector bars 26, it is easier to adjust the relative positional relationship between the connectors 14.

The connector bars 26 are attached to the connector bar attachment parts 24 so as to be slidable. Therefore, the plurality of connector bars 26 are arranged so as to be movable relative to each other in the direction in which they are arranged, and it is easier to adjust the relative positional relationship between the connectors 14. Consequently, it is possible to obtain a wire harness 10 that has a shape that is more similar to the shape of the wire harness 10 when mounted on a vehicle.

Also, when the electrical wires 12 are inserted into the connectors 14, the connectors 14 are held on the connector bars 26, and the connector bars 26 that were used when the electrical wires were inserted are used as they are when branches are formed. That is, the same connector bars 26 are used from when the electrical wires are inserted to when branches are formed. Consequently, it is possible to suppress the number of manufacturing steps from increasing due to the connectors 14 being re-mounted at the time of transition from the task of inserting electrical wires to the task of forming branches.

Also, since the distance from the connectors 14 is measured by obtaining the image data of the electrical wires 12 that dangle from the connectors 14 and processing the image data, and thus the positions at which branches are to be formed are determined, it is possible to realize automation of the task related to the formation of branches.

### Modifications

Next, modifications of the wire harness manufacturing method will be described. In the descriptions of the modifications, constituent elements that are the same as those in the embodiment are assigned the same reference numerals, and the descriptions of the elements are omitted.

In the embodiment, it is assumed that the insertion of electrical wires into the connectors 14 are fully automatically performed using the electrical wire inserting device 30. However, this is not essential. Part or all of the insertion of electrical wires into the connectors 14 may be manually performed. Also, even in the case where electrical wires are automatically inserted into the connectors 14, it is not essential to employ the electrical wire inserting device 30. An electrical wire inserting device other than the electrical wire inserting device 30 may be employed.

In the embodiment, it is assumed that the task of inserting electrical wires and the task of forming branches are performed in the state where the connectors 14 are supported by the same connector bars 26. However, this is not essential. For example, connectors into which electrical wires have been inserted or connector holding parts that hold the connectors may be attached to the connector bars 26. That is, the connector holding part supporting device is not necessarily used to perform the task of inserting electrical wires.

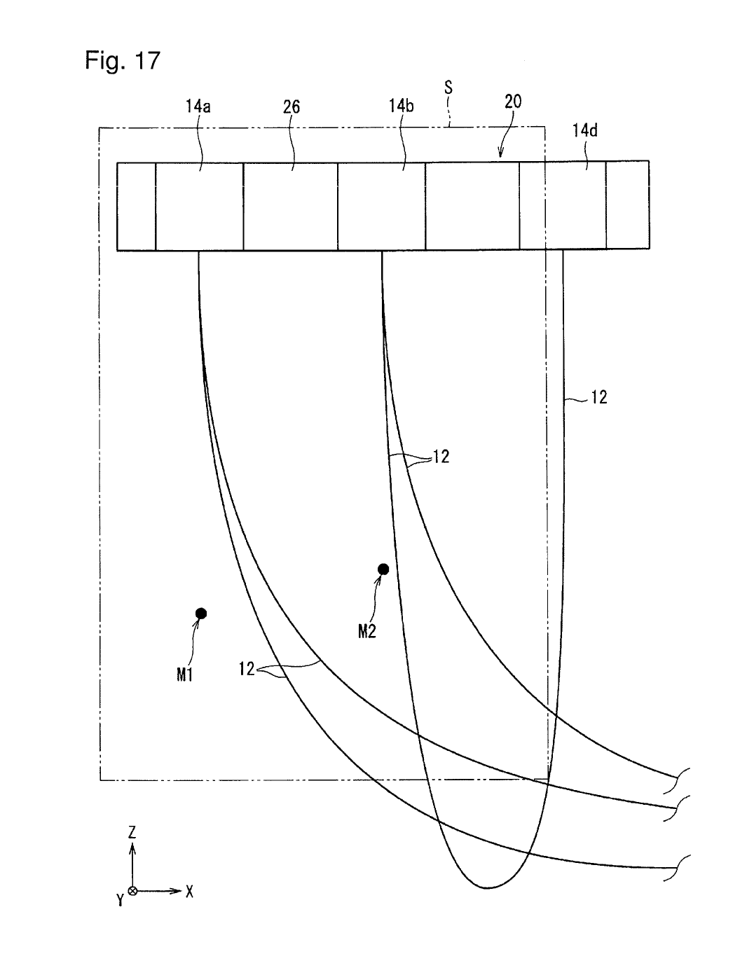

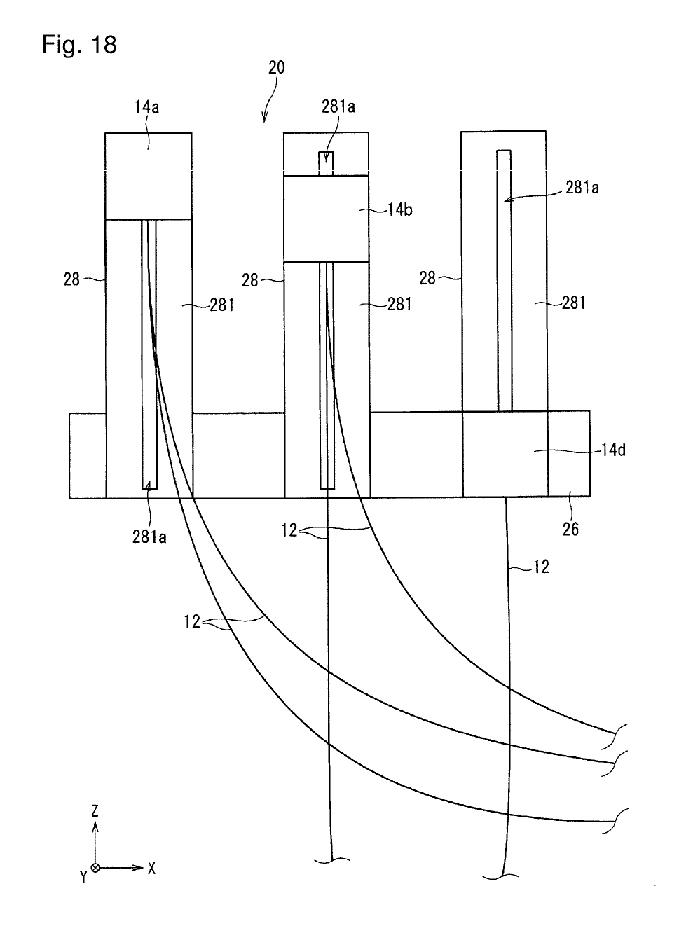

In the embodiment, it is assumed that branches of the electrical wires 12 are fully automatically formed using the electrical wire group processing device 50. However, this is not essential. Part or all of the formation of branches of the electrical wires 12 may be manually performed. In the case where at least part of the formation of branches of the electrical wires 12 is manually performed, examples shown in FIGS. 17 and 18 may be employed.

FIG. 17 illustrates a wire harness manufacturing method according to a modification. FIG. 18 illustrates a wire harness manufacturing method according to another modification. In the following description, it is assumed that the primary branching points are manually formed.

In the case where branches are manually formed, specifying the branching positions by measuring the distance from the connectors 14 one by one as with the electrical wire group processing device 50 is bothersome. Therefore, it is preferable that marks that make it possible to specify the branching positions are set so that the operator can easily specify the branching positions. In FIGS. 17 and 18, the marks are set in different manners.

That is, in the case of the wire harness manufacturing method according to FIG. 17, another object that serves as a mark is provided rearward of the electrical wires 12 when viewed from the operator. Here, a plate-shaped member S is provided rearward of the connector bars 26 when viewed from the operator, and marks M1 and M2 are provided at predetermined positions on the plate-shaped member. Here, the predetermined positions on the plate-shaped member S are positions at the above-described certain distance from the positions corresponding to the connectors 14a and 14b on the plate-shaped member S when the plate-shaped member S is located rearward of the connector bars 26 when viewed from the operator. The operator maintains the electrical wires 12 that extend from the connector 14a in a taut state such that the electrical wires 12 pass through the mark M1, and thus the operator can recognize that the position at the mark M1 is the position at which a primary branching point of the electrical wires 12 that extend from the connector 14a is to be formed. Similarly, the operator recognizes the position at which a primary branching point of the electrical wires 12 that extend from the connector 14b is to be formed, using the mark M2, and then collects the two sets of electrical wires 12 to the respective branching points to form branches.

In contrast, in the case of the wire harness manufacturing method according to FIG. 18, the connector holding part attachment parts 28 (the connector bars 26) serve as marks as themselves. More specifically, the connectors 14 are moved to slide on the connector holding part attachment parts 28 to the above-described certain distance from the connector bars 26. As a result, the edges of the connector holding part attachment parts 28 (the edges of the connector bars 26) serve as marks that indicate the positions at which primary branching points of the electrical wires 12 that extend from the connectors 14 are to be formed. The operator pulls the electrical wires 12 that extend from the connector 14a to the edge of the connector holding part attachment part 28 (the edge of the connector bar 26) in a taut state, and thus the operator can recognize the position at which the electrical wires 12 will overlap the edge of the connector holding part attachment part 28 (the edge of the connector bar 26) is the position at which a primary branching point of the connector 14a is to be formed. The operator similarly recognizes the position at which a primary branching point for the connector 14b is to be formed, and then collects the two sets of electrical wires 12 to the respective branching points to form branches.

In this way, when the operator forms branches, for example, the operator can more easily specify the positions at which branches are to be formed, by moving the connector holding parts 16 to slide relative to the connector holding part attachment parts 28 to match the positions of the connectors 14 relative to the connector bars 26 with the distance from the connectors 14 to the positions at which branches are to be formed.

In FIG. 17, the marks are provided at positions that are downward of the connectors 14 in the vertical direction. However, this is not essential. The positions of the marks may be upward of the connectors 14 in the vertical direction, or at a distance from the connectors 14 in the horizontal direction.

Also, even in the case of automatically forming branches of the electrical wires 12, it is possible to employ a device other than the electrical wire group processing device 50.

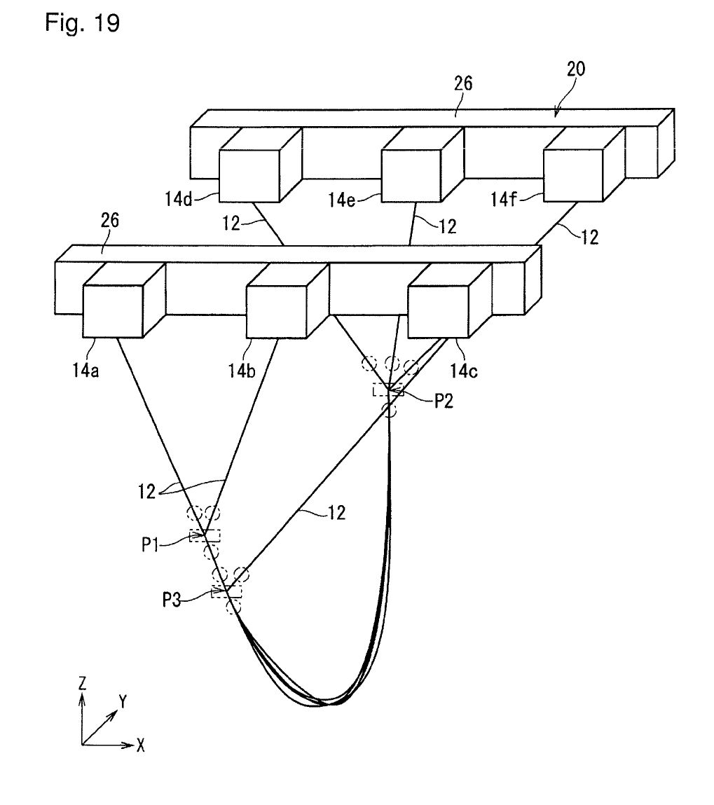

In the embodiment, it is assumed that, when branches of the electrical wires 12 are formed, three or more connectors 14 that are connected to one primary branching point are two-dimensionally arranged when viewed in the direction in which the electrical wires 12 are inserted. However, this is not essential. For example, as shown in FIG. 19, three or more connectors 14 that are connected to one primary branch may be one-dimensionally arranged (in a row) when viewed in the direction in which the electrical wires 12 are inserted.

FIG. 19 illustrates a wire harness manufacturing method according to yet another modification. In the case of wire harness manufacturing method according to FIG. 19, three connectors 14d, 14e, and 14f that are connected to one primary branching point are supported by one connector bar 26. With this configuration, branches are formed such that three or more connectors 14 that are connected to one primary branching point are one-dimensionally arranged (in a row) when viewed from the direction in which the electrical wires 12 are inserted. Using such a wire harness manufacturing method, it is possible to achieve the advantageous effects that are the same as those of the wire harness manufacturing method according to the embodiment, except the advantage in which the electrical wires 12 are prevented from twisting.

In the embodiment, it is assumed that the openings of the cavities 141 of the connectors 14 face downward in the vertical direction when branches of the electrical wires 12 are formed. However, this is not essential. For example, the openings of the cavities 141 of the connectors 14 face downward in the vertical direction when branches of the electrical wires 12 are formed. Specifically, for example, branches may be formed with the connector holding part supporting device 20 being orientated such that the lengthwise direction of the first rail portions 242 in the connector holding part supporting device 20 extend in the vertical direction.

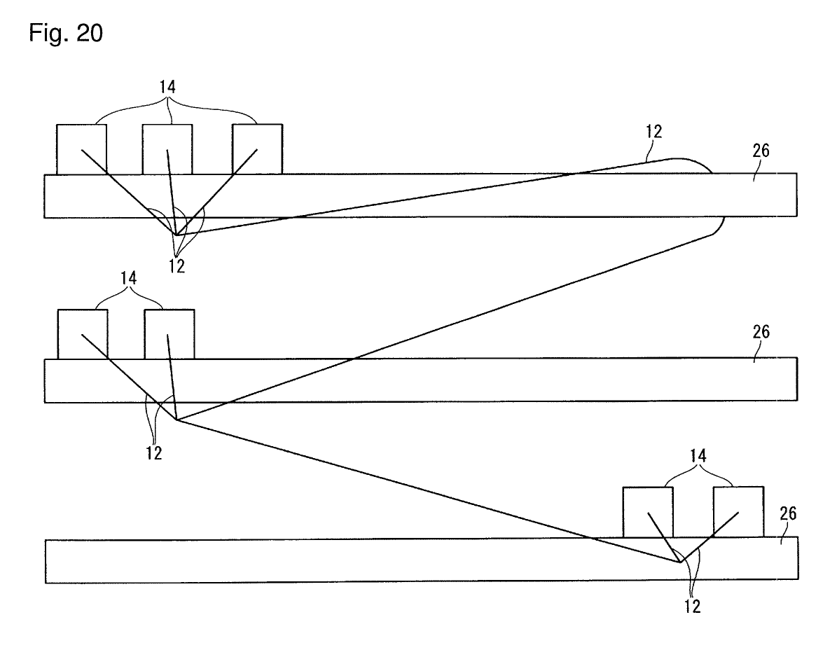

In the embodiment, it is assumed that all of the electrical wires 12 between the connectors 14 dangle. However, this is not essential. For example, as shown in FIG. 20, intermediate portions of the electrical wires 12 between the connectors 14 may be supported by, for example, being hung from a portion of the connector holding part supporting device 20 such as a connector bar 26, or a member that is separate from the connector holding part supporting device 20. If intermediate portions of the electrical wires 12 between the connectors 14 are supported, the electrical wires 12 are prevented from touching the frame 22 of the connector holding part, supporting device 20, the floor, or the like when the electrical wires 12 dangle, even if the electrical wires are long. Also, it is possible to retract the electrical wires 12 that hinder the formation of branches. In this regard, as shown in FIG. 20, it is possible to arrange the electrical wires 12 so as to meander, to form branches. Note that, in FIG. 20, the direction in which the connector bars 26 extend is the above-described x axis direction. The direction in which three connector bars 26 are arranged may be the y axis direction or the z axis direction.

Note that the configurations that have been described in the above-described embodiment and modifications can be combined as appropriate unless being inconsistent with one another.

Although the present invention has been described in detail above, the descriptions are to be considered in all respects as illustrative, and the present invention is not limited to the descriptions. It should be understood that innumerable modifications that are not illustrated herein can be envisaged without departing from the scope of the present invention.

### LIST OF REFERENCE NUMERALS

10: Wire Harness

12: Electrical Wire

14: Connector

16: Connector Holding Part

20: Connector Holding Part Supporting Device

26: Connector Bar

28: Connector Holding Part Attachment Part

30: Electrical Wire Inserting Device

40: Electrical Wire Fixing Mechanism

50: Electrical Wire Group Processing Device

60: Processing Robot

70: Image Acquisition System

D1: First image Data

D2: Second Image Data

1. A wire harness manufacturing method comprising:
preparing a member in which a plurality of connectors into which electrical wires are inserted are respectively held by connector holders such that the electrical wires dangle, and supports configured to support the connector holders in a first direction that is orthogonal to a vertical direction are arranged in a second direction that is orthogonal to the first direction; and
forming branches from portions of the electrical wires that dangle from the connectors while with the connectors are held by the connector holders.

2. The wire harness manufacturing method according to claim 1,
wherein forming the branches includes using connector holders configured to be movable relative to each other.

3. The wire harness manufacturing method according to claim 1,
wherein preparing the member includes using connector holders directly or indirectly attached to rod-shaped connector bars so as to be slidable in a lengthwise direction of the connector bars, the connector bars being provided in a direction that is orthogonal to the lengthwise direction thereof.

4. The wire harness manufacturing method according to claim 3,
wherein the connector holders are attached to connector holder attachment parts so as to be slidable in a direction that is orthogonal to the lengthwise direction of the connector bars, the connector holder attachment parts being attached to the connector bars so as to be slidable in the lengthwise direction of the connector bars.

5. The wire harness manufacturing method according to claim 3,
wherein the plurality of connector bars are configured to be movable relative to each other in a direction in which the connector bars are arranged.

6. The wire harness manufacturing method according to claim 3,
wherein the connectors are held on the connector bars when the electrical wires are inserted into the connectors, and
the connector bars used when the electrical wires are inserted are also used when the branches are formed.

7. The wire harness manufacturing method according to claim 1,
wherein forming the branches includes acquiring image data of the electrical wires dangling from the connectors, processing the image data to measure a distance from the connectors, and determining positions at which branches are to be formed.

8. A connector holder supporting device comprising:
a plurality of supports configured directly or indirectly support a plurality of connector holders such that electrical wires that extend from connectors held in the holders dangle,
wherein the supports are configured to support the plurality of connector holders such that the plurality of connector holders are movable in a first direction that is orthogonal to a vertical direction, and the plurality of supports are arranged in a second direction that is orthogonal to the first direction.
